(19) United States
(12) Patent Application Publication
(10) Pub. No.: US 2025/0393184 A1
(43) Pub. Date: Dec. 25, 2025

(54) SEMICONDUCTOR DEVICE

(71) Applicant: Samsung Electronics Co., Ltd., Suwon-si (KR)

(72) Inventors: Jaehyun Choi, Suwon-si (KR); Moonyoung Jeong, Suwon-si (KR)

(21) Appl. No.: 18/979,995

(22) Filed: Dec. 13, 2024

(30) Foreign Application Priority Data
Jun. 24, 2024 (KR) 10-2024-0081907

(51) Int. Cl. H10B 12/00; G11C 11/405; G11C 11/408; G11C 11/4091

(52) U.S. Cl. CPC H10B 12/00; G11C 11/405; G11C 11/4087; G11C 11/4091

(57) ABSTRACT

A semiconductor device may include: a plurality of memory cells connected to a plurality of word lines and a plurality of bit lines; a row decoder configured to control voltages on each of the plurality of word lines; and a sense amplifier circuit configured to control voltages on each of the plurality of bit lines. Each of the plurality of memory cells includes a pair of transistors. The row decoder is configured to provide a common control voltage to the pair of transistors included in a selected memory cell among the plurality of memory cells, through one select word line of the plurality of word lines, and a first transistor of the pair of transistors is turned on and a second transistor of the pair of transistors is turned off by the common control voltage.

### CROSS-REFERENCE TO RELATED APPLICATION(S)

This application claims the benefit of priority under 35 U.S.C. § 119 to Korean Patent Application No. 10-2024-0081907 filed on Jun. 24, 2024, in the Korean Intellectual Property Office, the disclosure of which is incorporated herein by reference in its entirety.

### BACKGROUND

The present disclosure relates generally to a semiconductor device.

A semiconductor device may provide a function to write and erase data to or from memory cells, or to read written data from memory cells. A memory cell may include a switch element turned on during a write operation for writing data, a read operation for reading data, or the like. In order to improve the performance of a semiconductor device, it is necessary to improve both the on/off characteristics that have a trade-off relationship in the switch element, and to this end, a method of implementing one memory cell with two switch elements has been proposed. However, when implementing one memory cell with two switch elements, the number of word lines connected to the switch elements increases, which may make the structure complex, or the switch elements may be turned on simultaneously during the write operation and/or the read operation, which may increase power consumption.

### SUMMARY

An aspect of the present disclosure is to provide a semiconductor device that may enable one memory cell to be controlled by one word line and may reduce power consumption by turning on only one of multiple switch elements during a write operation and a read operation, by implementing a memory cell with two switch elements that are complementary to each other.

According to an aspect of the present disclosure, there is provided a semiconductor device including: a cell region in which a plurality of unit structures are arranged in a first direction, perpendicular to an upper surface of a substrate, and a second direction and a third direction, parallel to the upper surface of the substrate, and intersecting each other; and a peripheral circuit region in which circuits controlling the cell region are disposed, and each of the plurality of unit structures may include: a first gate electrode layer and a second gate electrode layer separated from each other in the first direction and extending in the second direction; a first semiconductor layer and a second semiconductor layer separated from each other in the first direction and between the first gate electrode layer and the second gate electrode layer in the first direction, and extending in the third direction; a plurality of insulating layers between the first gate electrode layer, the second gate electrode layer, the first semiconductor layer and the second semiconductor layer in the first direction; and a bit line electrode layer extending in the first direction and connected to the first semiconductor layer and the second semiconductor layer in the third direction.

According to an aspect of the present disclosure, there is provided a semiconductor device including: a cell region in which a plurality of memory cells connected to a plurality of word lines and a plurality of bit lines are disposed; and a peripheral circuit region in which circuits controlling the plurality of memory cells through the plurality of word lines and the plurality of bit lines are disposed, and each of the plurality of memory cells may include a first transistor and a second transistor. The first transistor includes a first gate and first active regions, and the second transistor includes a second gate and second active regions. In each of the plurality of memory cells, the first gate and the second gate are commonly connected to one of the plurality of word lines, one of the first active regions and one of the second active regions may be commonly connected to one of the plurality of bit lines, the other one of the first active regions may be connected to a ground node supplying a ground voltage, and the other one of the second active regions may provide a storage node in which the charge is stored.

According to an aspect of the present disclosure, there is provided a semiconductor device including: a plurality of memory cells connected to a plurality of word lines and a plurality of bit lines; a row decoder configured to control voltages of each of the plurality of word lines; and a sense amplifier circuit configured to control voltages of each of the plurality of bit lines, and each of the plurality of memory cells may include a pair of transistors, the row decoder may input a common control voltage to the pair of transistors included in a select memory cell among the plurality of memory cells, through one select word line of the plurality of word lines, and one of the pair of transistors may be turned on and the other one of the pair of transistors is turned off, by the common control voltage.

According to an example embodiment of the present disclosure, each of the memory cells may include a first transistor and a second transistor, and one of the first transistor and the second transistor may be turned on only during a write operation and the other thereof may be turned on only during a read operation. By preventing the first transistor and the second transistor from being turned on simultaneously, the power consumption of the semiconductor device may be reduced. Additionally, by connecting the first transistor and the second transistor to one word line in common, the semiconductor device may be implemented without increasing the number of word lines. Additionally, by implementing a memory cell capable of storing data without a capacitor, retention characteristics of the memory cell may be improved as compared to a memory cell recording data by charging and discharging a capacitor.

Advantages and effects of the present application are not limited to the foregoing content and may be more easily understood in the process of describing specific example embodiments of the present disclosure.

### BRIEF DESCRIPTION OF DRAWINGS

The above and other aspects, features, and advantages of the present disclosure will be more clearly understood from the following detailed description, taken in conjunction with the accompanying drawings, wherein like reference numerals (when used) indicate corresponding elements throughout the several views, and in which:

FIG. 1 is a block diagram simply illustrating a semiconductor device according to an example embodiment of the present disclosure;

FIG. 2 is a schematic view illustrating at least a portion of a memory cell array included in a semiconductor device according to an example embodiment of the present disclosure;

FIG. 3 is a graph illustrating certain characteristics of a memory cell included in a semiconductor device according to an example embodiment of the present disclosure;

FIG. 4A to FIG. 4D and FIG. 5A to FIG. 5F are views conceptually illustrating a write operation of a semiconductor device according to an example embodiment of the present disclosure;

FIG. 6A to FIG. 6D and FIG. 7A to FIG. 7F are views conceptually illustrating a read operation of a semiconductor device according to an example embodiment of the present disclosure;

FIG. 8A to FIG. 8D are schematic views simply illustrating a semiconductor device according to an example embodiment of the present disclosure;

FIG. 9 to FIG. 58 are schematic top plan and cross-sectional views illustrating intermediate processes in a method of manufacturing a semiconductor device according to an example embodiment of the present disclosure;

FIG. 59 and FIG. 60 are views illustrating a neural network that may be implemented with a semiconductor device according to an example embodiment of the present disclosure; and

FIGS. 61 to 63 are schematic views conceptually illustrating an operation of a semiconductor device according to an example embodiment of the present disclosure.

### DETAILED DESCRIPTION

Hereinafter, example embodiments of the present disclosure will be described with reference to the accompanying drawings.

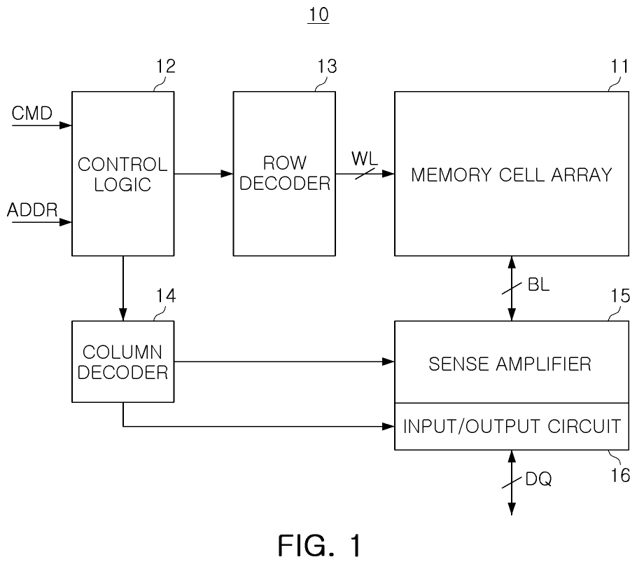

FIG. 1 is a block diagram simply illustrating a semiconductor device according to an example embodiment of the present disclosure.

Referring to FIG. 1, a semiconductor device 10 according to an example embodiment of the present disclosure may be a storage device based on a semiconductor element. The semiconductor device 10 may be a random access memory (RAM) device such as a Dynamic Random Access Memory (DRAM), a Synchronous DRAM (SDRAM), a Static RAM (SRAM), a Double Date Rate SDRAM (DDR SDRAM), a DDR2 SDRAM, a DDR3 SDRAM, a Phase-change RAM (PRAM), a Magnetic RAM (MRAM), a Resistive RAM (RRAM), or the like. The semiconductor device 10 may store data received through a data signal DQ, or output data as a data signal DQ, in response to an address signal ADDR and a control command signal CMD received from an external host (e.g., a central processing unit (CPU), an application processor (AP), a system on a chip (SoC), etc., not explicitly shown).

The semiconductor device 10 may include a memory cell array 11, a control logic 12, a row decoder 13, a column decoder 14, a sense amplifier 15, and an input/output circuit 16. The memory cell array 11 may be disposed in a cell region of the semiconductor device 10, and the control logic 12, the row decoder 13, the column decoder 14, the sense amplifier 15, and the input/output circuit 16 may be disposed in a peripheral circuit region of the semiconductor device 10 to control the cell region.

The memory cell array 11 may include a plurality of memory cells, and the plurality of memory cells may be connected to the row decoder 13 and the sense amplifier 15 through a plurality of word lines WL and a plurality of bit lines BL. Each of the plurality of memory cells may be disposed at a point at which the plurality of word lines WL and the plurality of bit lines BL intersect each other. The plurality of memory cells may be arranged in a matrix form in the memory cell array 11. Each of the plurality of memory cells may include a pair of transistors, for example, a first transistor and a second transistor, and a first gate of the first transistor and a second gate of the second transistor may be commonly connected to one word line.

In an example embodiment of the present disclosure, each of the plurality of memory cells may not include a capacitor. At least one of the first transistor and the second transistor may include a storage node, and data may be written to each of the memory cells in a manner of storing charges in the storage node.

The control logic 12 may receive the address signal ADDR and the control command signal CMD from an external host (not explicitly shown). The address signal ADDR may include a row address indicating a row in the memory cell array 11 and a column address indicating a column in the memory cell array 11. For example, the row decoder 13 may determine at least one select word line among the plurality of word lines WL by referring to the row address, and the column decoder 14 may determine at least one select bit line among the plurality of bit lines BL by referring to the column address.

A voltage applied by the row decoder 13 to the select word line may be applied as a common control voltage to the first transistor and the second transistor included in each of select memory cells connected to the select word line. The first transistor and the second transistor in each of the memory cells may have different threshold voltages, and the first transistor and the second transistor may be selectively turned on by the common control voltage applied to the select word line.

For example, when the row decoder 13 applies a common control voltage to the select word line to perform a write operation, a read operation, or the like, one of the first transistor and the second transistor may be turned on and the other thereof may be turned off. Accordingly, the first transistor and the second transistor are not turned on at the same time in the write operation and the read operation, and the power consumption of the semiconductor device 10 may be reduced and retention characteristics may be improved.

The sense amplifier 15 may include a plurality of bit line sense amplifiers connected to the memory cell array 11 through the plurality of bit lines BL. For example, when the read operation is performed, the bit line sense amplifier connected to the select bit line selected by the column decoder 14 may read data of at least one of the select memory cells connected to the select bit line. The input/output circuit 16 may output the data read by the bit line sense amplifier as a data signal DQ.

In an example embodiment, in the write operation, the voltage of the select bit line selected by the column decoder 14 may be set to a predetermined precharge level. The precharge level may be determined according to data to be stored in the select memory cell connected to the select bit line. When the row decoder 13 applies a predetermined voltage to the select word line in a state in which the voltage of the select bit line is set to the precharge level, one of the first transistor and the second transistor of the select memory cell may be turned on so that charges may be stored in the storage node or charges may be removed from the storage node.

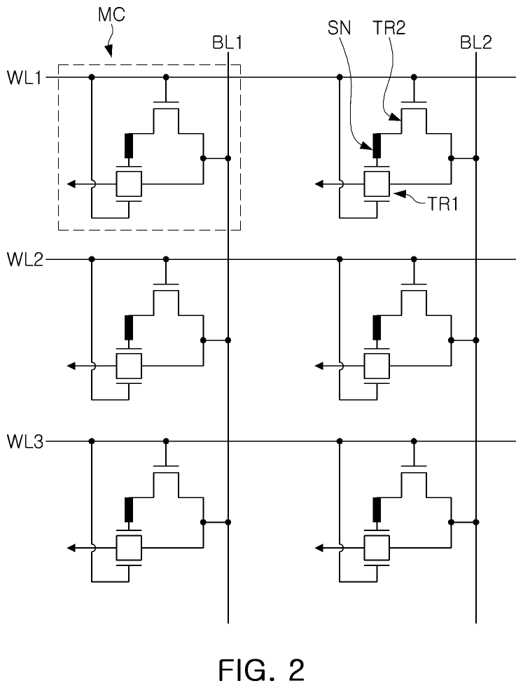

FIG. 2 is a schematic view illustrating at least a portion of a memory cell array included in a semiconductor device according to an example embodiment of the present disclosure.

Referring to FIG. 2, the memory cell array according to an example embodiment of the present disclosure may include a plurality of memory cells MC connected to a plurality of word lines WL1 to WL3 and a plurality of bit lines BL1 to BL2. The number of the plurality of word lines WL1 to WL3, the plurality of bit lines BL1 to BL2, and the plurality of memory cells MC may vary according to an example embodiment. The plurality of memory cells MC may be disposed at points at which the plurality of word lines WL1 to WL3 and the plurality of bit lines BL1 to BL2 intersect each other.

Each of the plurality of memory cells MC may include a first transistor TR1 and a second transistor TR2. A gate of the first transistor TR1 and a gate of the second transistor TR2 may be commonly connected to a corresponding one of the plurality of word lines WL1 to WL3. One of the active regions (e.g., a first source/drain region) of the first transistor TR1 may be connected to a reference node supplying a reference voltage (e.g., a ground voltage), and the other thereof (e.g., a second source/drain region) may be connected to a corresponding one of the bit lines BL1 to BL2.

Meanwhile, one of the active regions of the second transistor TR2 may provide a storage node SN of the memory cell MC, and the other one of the active regions of the second transistor TR2 may be connected to one of the bit lines BL1 to BL2. Accordingly, the first transistor TR1 and the second transistor TR2 may be commonly connected to one of the bit lines BL1 to BL2. In each of the plurality of memory cells MC, the storage node SN may be electrically connected to a back gate of the first transistor TR1. A voltage applied to the back gate of the first transistor TR1 has the effect of raising or lowering the threshold voltage of the transistor as a function of the applied voltage. For example, in an n-channel metal-oxide semiconductor (NMOS) transistor, a positive back gate voltage increases the threshold voltage of the transistor (i.e., harder to turn on), while a negative back gate voltage lowers the threshold voltage of the transistor (i.e., easier to turn on).

In an example embodiment of the present disclosure, one of the first transistor TR1 and the second transistor TR2 may be turned on only during a write operation for writing data to the memory cell MC, and the other of the first transistor TR1 and the second transistor TR2 may be turned on only during a read operation for reading data from the memory cell MC. In order to implement the operation, the first transistor TR1 and the second transistor TR2 may be formed to have different threshold voltages. For example, one of the first transistor TR1 and the second transistor TR2 may be a p-channel metal-oxide semiconductor (PMOS) transistor, and the other thereof may be an NMOS transistor.

For example, assuming that the first transistor TR1 is the NMOS transistor and the second transistor TR2 is the PMOS transistor, a positive voltage greater than the threshold voltage of the first transistor TR1 may be input to the word line, so that only the first transistor TR1 may be turned on and the second transistor TR2 may be turned off. On the other hand, a negative voltage lower than a threshold voltage of the second transistor TR2 may be input to the word line, so that the first transistor TR1 may be turned off and only the second transistor TR2 may be turned on.

However, the example embodiments of the present disclosure are not necessarily limited to the first transistor TR1 being the NMOS transistor and the second transistor TR2 being the PMOS transistor. For example, both the first transistor TR1 and the second transistor TR2 may be NMOS transistors or PMOS transistors, or the first transistor TR1 may be the PMOS transistor and the second transistor TR2 may be the NMOS transistor.

Assuming a general structure in which each of the memory cells MC includes one transistor and one capacitor, the retention characteristics of each of the memory cells MC may be improved by increasing the threshold voltage of the transistor, while tRDL (allowed time interval between data-in and word-line pre-charge) parameter for determining the write operation characteristics may be degraded. Accordingly, in a structure in which each of the memory cells MC includes only one transistor, there may be a limit to simultaneously improving the retention characteristics and the write operation characteristics.

In an example embodiment of the present disclosure, wherein the transistors turned on during the write operation and the transistors turned on during the read operation may be separated from each other, both the retention characteristics and the write operation characteristics of the memory cells MC may be improved. For example, the transistors turned on during the write operation may be designed to have a relatively small threshold voltage and the transistors turned on during the read operation may be designed to have a relatively high threshold voltage, thereby improving both the retention characteristics and the write operation characteristics of the memory cells MC. For example, in an example embodiment illustrated in FIG. 2, a threshold voltage of the first transistor TR1 allocated for read operation may have an absolute value greater than a threshold voltage of the second transistor TR2 allocated for write operation.

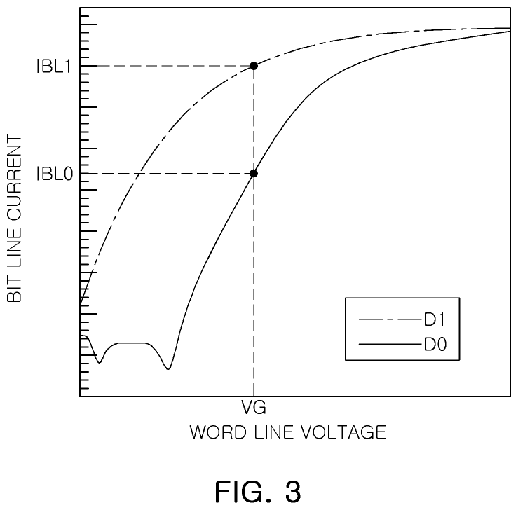

FIG. 3 is a graph illustrating certain characteristics of a memory cell included in a semiconductor device according to an example embodiment of the present disclosure.

Referring to FIG. 3, a graph simply illustrates voltage/current characteristics according to data stored in a memory cell in a semiconductor device according to an example embodiment of the present disclosure. In the graph of FIG. 3, a horizontal axis may correspond to a voltage of a word line connected to a memory cell, and a vertical axis may correspond to a current of a bit line connected to the memory cell.

A first plot (D0) of FIG. 3 may illustrate the voltage/current characteristics of a memory cell in which first data is written, and a second plot (D1) may illustrate the voltage/current characteristics of a memory cell in which second data is written. In the example embodiment illustrated in FIG. 3, the first data may correspond to bit “0” (i.e., logic “0”), and the second data may correspond to bit “1” (i.e., logic “1”).

The memory cell may include a first transistor and a second transistor having different threshold voltages as described above with reference to FIG. 2, and one of the active regions of the first transistor or the second transistor may provide a storage node of the memory cell. The write operation for the memory cell may be performed by storing charges in the storage node or removing charges stored in the storage node. For example, a first data may be written to the memory cell by removing charges stored in the storage node, and a second data may be written to the memory cell by storing charges in the storage node.

In a state in which charge is not stored in the storage node, that is, in a state in which the first data (i.e., logic “0”) is written to the memory cell, a predetermined gate voltage VG may be applied to the word line, thereby enabling a first bit line current IBL0 to flow in the bit line connected to the memory cell. Meanwhile, in a state in which charges are stored in the storage node, that is, in a state in which the second data (i.e., logic “1”) is written to the memory cell, the gate voltage VG may be applied to the word line, thereby enabling a second bit line current IBL1 to flow in the bit line. The second bit line current IBL1 may be greater than the first bit line current IBL0.

This may be because the threshold voltage of the transistor turned on during the read operation changes due to a potential of the storage node. As described above with reference to FIG. 2, the storage node may be electrically connected to a back gate of the transistor turned on during the read operation. In a state in which charges are stored in the storage node, the threshold voltage of the transistor may decrease as illustrated in the second graph (D1) of FIG. 3, and therefore, a relatively large second bit line current IBL1 may flow under the condition in which the gate voltage VG is applied to the word line.

On the other hand, in a state in which the charges stored in the storage node are removed, a relatively small first bit line current IBL0 may flow under the condition that the gate voltage VG is applied to the word line. The semiconductor device may read the data written to the memory cell as one of the first data and the second data based on a difference between the first bit line current IBL0 and the second bit line current IBL1.

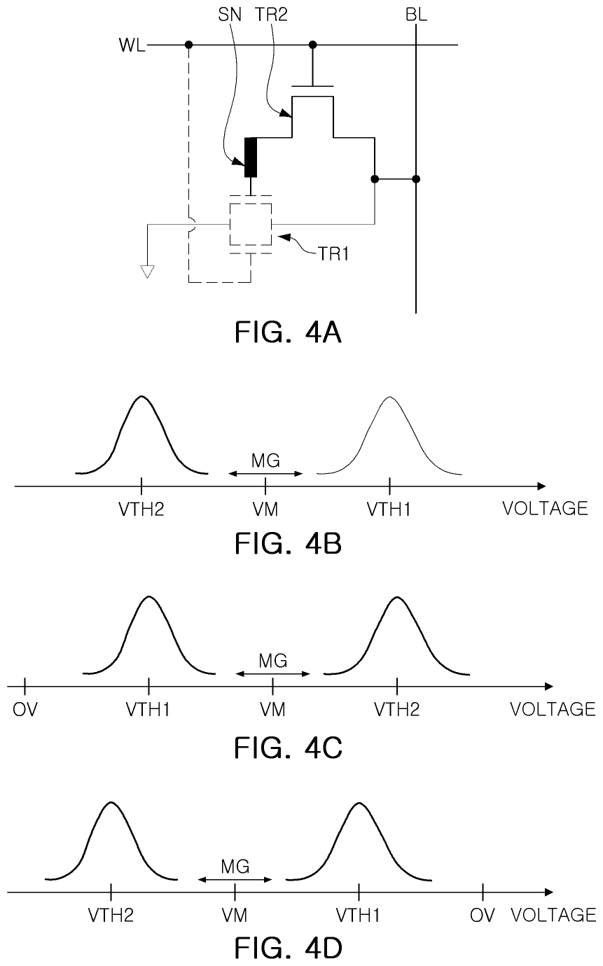

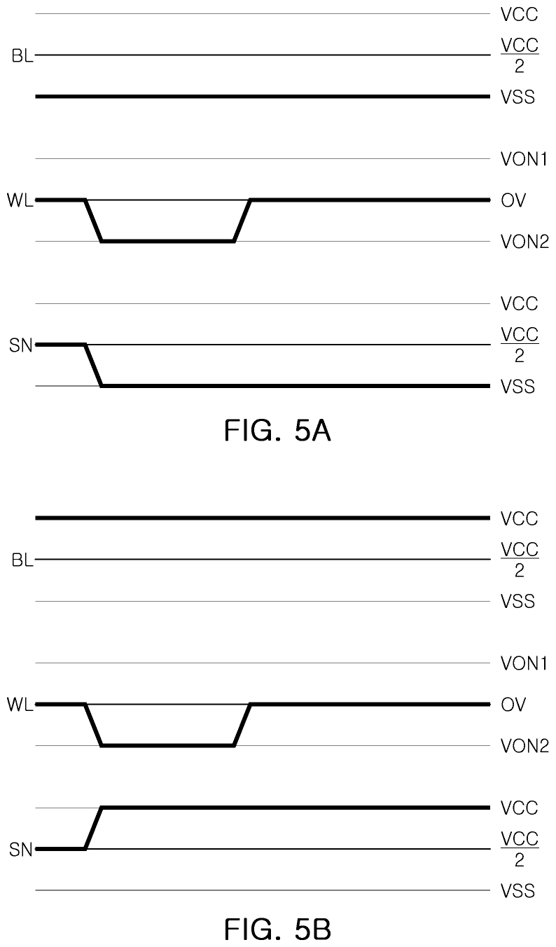

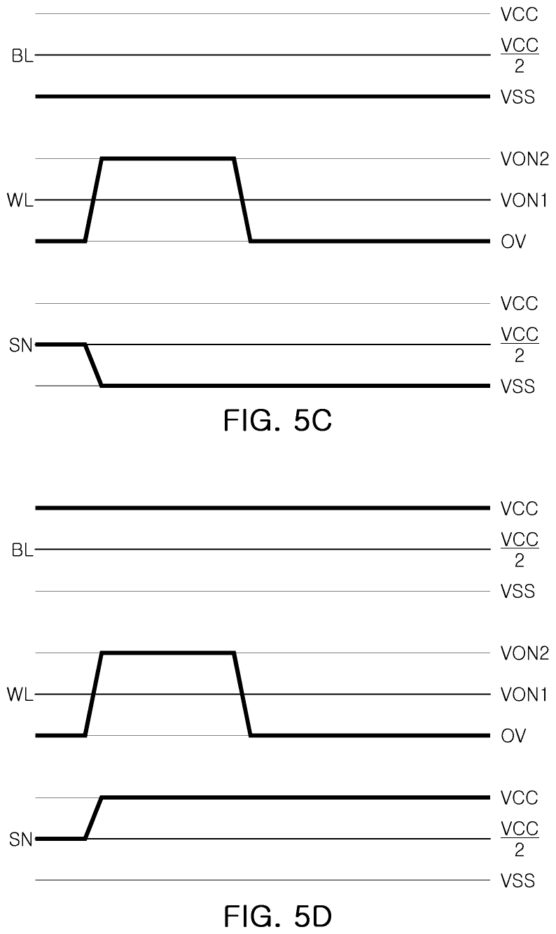

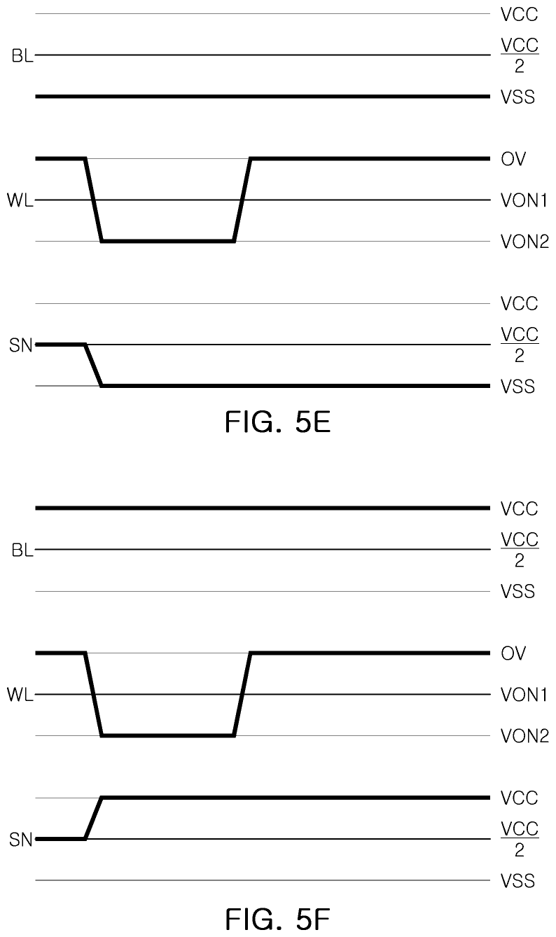

FIGS. 4A to 4D and FIGS. 5A to 5F are views conceptually illustrating a write operation of a semiconductor device according to an example embodiment of the present disclosure.

Referring to FIG. 4A, a memory cell included in a semiconductor device according to an example embodiment of the present disclosure may include a first transistor TR1 and a second transistor TR2. The memory cell in FIG. 4A may be configured in a manner consistent with a memory cell MC shown in FIG. 2. Specifically, the first transistor TR1 and the second transistor TR2 may be commonly connected to a corresponding word line WL and a corresponding bit line BL. A storage node SN may be provided by one of the active regions of the second transistor TR2, and may be electrically connected to a back gate of the first transistor TR1. The first transistor TR1 may be a transistor for a read operation, and the second transistor TR2 may be a transistor for a write operation.

FIGS. 4B to 4D are views illustrating example threshold voltage distributions of the first transistor TR1 and the second transistor TR2 included in the memory cell. Referring to FIGS. 4B to 4D, based on an intermediate voltage VM, the first transistor TR1 may have a first threshold voltage VTH1 higher than the intermediate voltage VM, and the second transistor TR2 may have a second threshold voltage VTH2 lower than the intermediate voltage VM. Accordingly, a predetermined voltage margin MG may exist between a threshold voltage distribution of the first transistor TR1 and a threshold voltage distribution of the second transistor TR2.

FIG. 4B illustrates a threshold voltage distribution in a memory cell in which the first transistor TR1 is an NMOS transistor and the second transistor TR2 is a PMOS transistor. In a write operation, only the second transistor TR2 may be turned on by applying a second turn-on voltage lower than the second threshold voltage VTH2 to the word line WL.

As illustrated in FIG. 4B, a write operation in a memory cell in which the first transistor TR1 is an NMOS transistor and the second transistor TR2 is a PMOS transistor will be described with reference to FIGS. 5A and 5B. FIG. 5A may be a view (a timing diagram) illustrating a write operation for removing charges from a storage node SN, and FIG. 5B may be a view (a timing diagram) illustrating a write operation for storing (i.e., adding) charges in the storage node SN. First, referring to FIG. 5A, in a state in which a voltage of the bit line BL is reduced from a bit line reference voltage VCC/2 to a first power supply voltage VSS, a voltage of the word line WL may be reduced to a second turn-on voltage VON2 less than 0 V.

The second turn-on voltage VON2 may be a voltage less than a second threshold voltage VTH2 of the second transistor TR2. Accordingly, in a state in which the first transistor TR1 is turned off, only the second transistor TR2 may be turned on, the bit line BL and the storage node SN may be electrically connected via the second transistor TR2, and the charges of the storage node SN may be removed through the bit line BL. Referring to FIG. 5A, a voltage of the storage node SN may be reduced from the bit line reference voltage VCC/2 to the first power supply voltage VSS.

Next, referring to FIG. 5B, in a state in which the voltage of the bit line BL is boosted from the bit line reference voltage VCC/2 to a second power supply voltage VCC, the voltage of the word line WL may be changed from a standby voltage of OV to a second turn-on voltage VON2, lower than the second threshold voltage VTH2. Accordingly, in a state in which the first transistor TR1 is turned off, only the second transistor TR2 may be turned on, and the bit line BL and the storage node SN may be electrically connected to each other via the second transistor TR2, so that charges may move from the bit line BL to the storage node SN. Referring to FIG. 5B, the voltage of the storage node SN may be increased by the second power supply voltage VCC.

FIG. 4C is a graph illustrating a threshold voltage distribution in a memory cell in which both the first transistor TR1 and the second transistor TR2 are NMOS transistors. In a memory cell in which both the first transistor TR1 and the second transistor TR2 are NMOS transistors, the second threshold voltage VTH2 of the second transistor TR2 may be higher than the first threshold voltage VTH1 of the first transistor TR1. Hereinafter, the write operation in the memory cell in which both the first transistor TR1 and the second transistor TR2 are NMOS transistors will be described with reference to FIGS. 5C and 5D.

FIG. 5C is a view (a timing diagram) illustrating a write operation for removing charges from a storage node SN, and FIG. 5D may be a view (a timing diagram) illustrating a write operation for storing (i.e., adding) charges in a storage node SN. First, referring to FIG. 5C, in a state in which the voltage of the bit line BL is set to a first power supply voltage VSS, lower than the bit line reference voltage VCC/2, the voltage of the word line WL may be increased to a second turn-on voltage VON2.

The second turn-on voltage VON2 may be a voltage higher than the second threshold voltage VTH2 of the second transistor TR2. Accordingly, both the first transistor TR1 and the second transistor TR2 may be turned on, the bit line BL and the storage node SN may be electrically connected via the second transistor TR2, and the charges of the storage node SN may be removed through the bit line BL. Referring to FIG. 5C, the voltage of the storage node SN may be decreased from the bit line reference voltage VCC/2 to the first power supply voltage VSS.

Next, referring to FIG. 5D, in a state in which the voltage of the bit line BL is boosted from the bit line reference voltage VCC/2 to the second power supply voltage VCC, the voltage of the word line WL may be increased to the second turn-on voltage VON2. Accordingly, the first transistor TR1 and the second transistor TR2 may be turned on, and the bit line BL and the storage node SN may be electrically connected to each other, so that the charges may move from the bit line BL to the storage node SN. Referring to FIG. 5D, the voltage of the storage node SN may be increased from the bit line reference voltage VCC/2 to the second power supply voltage VCC.

FIG. 4D is a graph illustrating a threshold voltage distribution in a memory cell in which both the first transistor TR1 and the second transistor TR2 are PMOS transistors. In the memory cell in which both the first transistor TR1 and the second transistor TR2 are PMOS transistors, the second threshold voltage VTH2 of the second transistor TR2 may be lower than the first threshold voltage VTH1 of the first transistor TR1. Hereinafter, a write operation in the memory cell in which both the first transistor TR1 and the second transistor TR2 are PMOS transistors will be described with reference to FIGS. 5E and 5F.

FIG. 5E may be a view (a timing diagram) illustrating a write operation for removing charges from a storage node SN, and FIG. 5F may be a view (a timing diagram) illustrating a write operation for storing charges in a storage node SN. First, referring to FIG. 5E, in a state in which the voltage of the bit line BL is set to a first power supply voltage VSS, lower than the bit line reference voltage VCC/2, the voltage of the word line WL may be decreased to a second turn-on voltage VON2, lower than 0 V.

The second turn-on voltage VON2 may be a voltage, lower than the second threshold voltage VTH2 of the second transistor TR2. Accordingly, both the first transistor TR1 and the second transistor TR2 may be turned on, the bit line BL and the storage node SN may be electrically connected to each other, and the charges of the storage node SN may be removed through the bit line BL. Referring to FIG. 5E, the voltage of the storage node SN may be decreased from the bit line reference voltage VCC/2 to the first power supply voltage VSS.

Next, referring to FIG. 5F, in a state in which the voltage of the bit line BL is boosted from the bit line reference voltage VCC/2 to the second power supply voltage VCC, the voltage of the word line WL may be decreased from the standby voltage of OV to the second turn-on voltage VON2. Accordingly, the first transistor TR1 and the second transistor TR2 may be turned on, and the bit line BL and the storage node SN may be electrically connected to each other, so that charges may move from the bit line BL to the storage node SN. Referring to FIG. 5F, the voltage of the storage node SN may be increased to the second power supply voltage VCC.

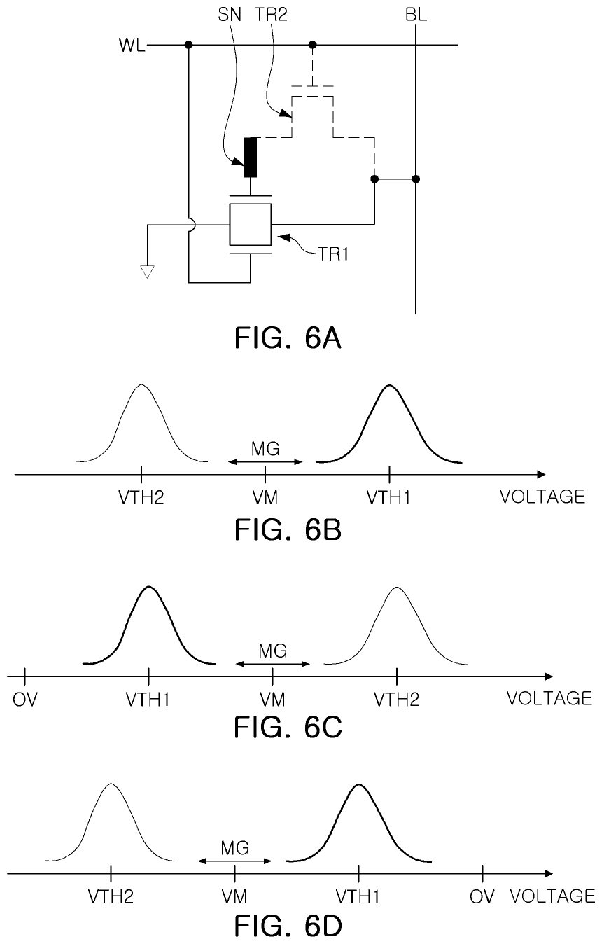

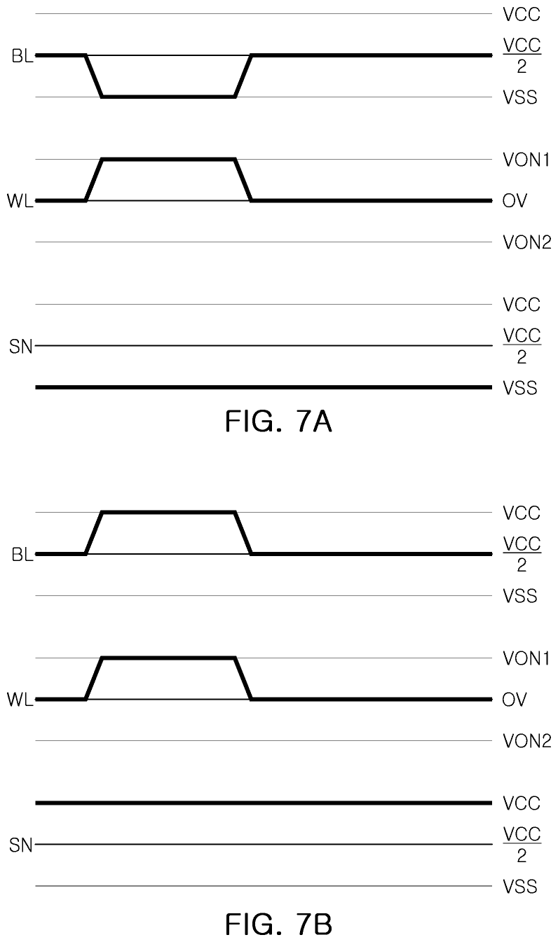

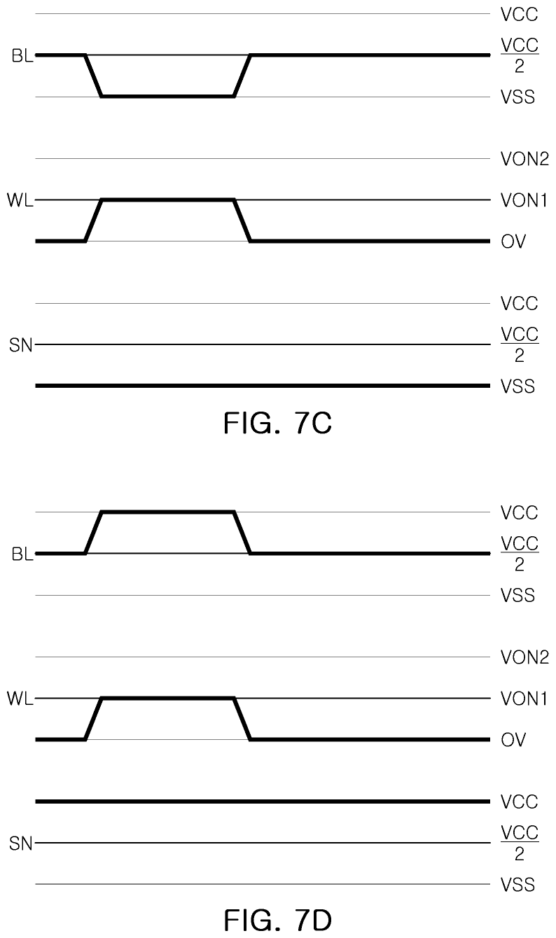

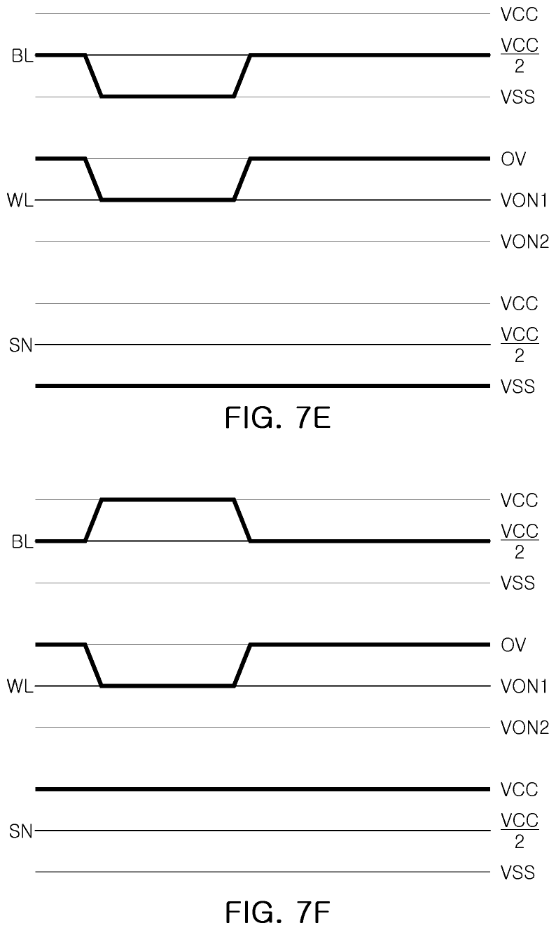

FIGS. 6A to 6D and FIGS. 7A to 7F are views conceptually illustrating a read operation of a semiconductor device according to an example embodiment of the present disclosure.

Referring to FIG. 6A, a memory cell included in a semiconductor device according to an example embodiment of the present disclosure may include a first transistor TR1 and a second transistor TR2 commonly connected to a word line WL and a bit line BL in a manner consistent with a configuration of the memory cell MC shown in FIG. 2. A storage node SN may be provided by one of active regions of the second transistor TR2, and may be electrically connected to a back gate of the first transistor TR1. Meanwhile, based on an intermediate voltage VM, the first transistor TR1 may have a first threshold voltage VTH1, higher than the intermediate voltage VM, and the second transistor TR2 may have a second threshold voltage VTH2, lower than the intermediate voltage VM. A predetermined voltage margin MG may be present between a threshold voltage distribution of the first transistor TR1 and a threshold voltage distribution of the second transistor TR2.

FIG. 6B is a graph illustrating a threshold voltage distribution in a memory cell in which the first transistor TR1 is an NMOS transistor and the second transistor TR2 is a PMOS transistor. In a read operation, only the first transistor TR1 may be turned on by applying a first turn-on voltage higher than the first threshold voltage VTH1 to the word line WL.

As illustrated in FIG. 6B, the read operation in the memory cell in which the first transistor TR1 is the NMOS transistor and the second transistor TR2 is the PMOS transistor will be described with reference to FIGS. 7A and 7B. FIG. 7A is a view (timing diagram) illustrating a read operation for reading data from a memory cell in which no charges are stored in a storage node SN, and FIG. 7B may be a view (timing diagram) illustrating a read operation for reading data from a memory cell in which charges are stored in a storage node SN.

First, referring to FIG. 7A, in a state in which a voltage of the bit line BL is set to a bit line reference voltage VCC/2, a first turn-on voltage VON1, higher than the first threshold voltage VTH1, may be applied to the word line WL. Accordingly, in a state in which the second transistor TR2 is turned off, only the first transistor TR1 may be turned on. Since the charges are not stored in the storage node SN, the voltage of the bit line BL may be decreased as illustrated in FIG. 7A.

Next, referring to FIG. 7B, in a state in which the voltage of the bit line BL is set to the bit line reference voltage VCC/2, a first turn-on voltage VON1, higher than the first threshold voltage VTH1, may be applied to the word line WL. Accordingly, in the state in which the second transistor TR2 is turned off, only the first transistor TR1 may be turned on. The voltage of the bit line BL may be increased as illustrated in FIG. 7B by the charges stored in the storage node SN.

FIG. 6C is a graph illustrating a threshold voltage distribution in a memory cell in which both the first transistor TR1 and the second transistor TR2 are NMOS transistors. In the memory cell in which both the first transistor TR1 and the second transistor TR2 are NMOS transistors, a second threshold voltage VTH2 of the second transistor TR2 may be higher than the first threshold voltage VTH1 of the first transistor TR1. Hereinafter, a read operation in the memory cell in which both the first transistor TR1 and the second transistor TR2 are NMOS transistors will be described with reference to FIGS. 7C and 7D.

FIG. 7C may be a view (timing diagram) illustrating a read operation for reading data from a memory cell in which no charges are stored in a storage node SN, and FIG. 7D may be a view illustrating a read operation for reading data from a memory cell in which charges are stored in a storage node SN. First, referring to FIG. 7C, in the state in which the voltage of the bit line BL is set to the bit line reference voltage VCC/2, a first turn-on voltage VON1, higher than the first threshold voltage VTH1, may be applied to the word line WL. Accordingly, in the state in which the second transistor TR2 is turned off, only the first transistor TR1 may be turned on. Since the charges are not stored in the storage node SN, the voltage of the bit line BL may be decreased as illustrated in FIG. 7C.

Next, referring to FIG. 7D, in the state in which the voltage of the bit line BL is set to the bit line reference voltage VCC/2, a first turn-on voltage VON1, higher than the first threshold voltage VTH1, may be applied to the word line WL. Accordingly, in the state in which the second transistor TR2 is turned off, only the first transistor TR1 may be turned on. The voltage of the bit line BL may be increased as illustrated in FIG. 7D by the charges stored in the storage node SN.

FIG. 6D may be a view (timing diagram) illustrating a threshold voltage distribution in a memory cell in which both the first transistor TR1 and the second transistor TR2 are PMOS transistors. In the memory cell in which both the first transistor TR1 and the second transistor TR2 are PMOS transistors, the second threshold voltage VTH2 of the second transistor TR2 may be lower than the first threshold voltage VTH1 of the first transistor TR1. Hereinafter, a read operation in the memory cell in which both the first transistor TR1 and the second transistor TR2 are PMOS transistors will be described with reference to FIGS. 7E and 7F.

FIG. 7E may be a view (timing diagram) illustrating a read operation for reading data from a memory cell in which no charges are stored in a storage node SN, and FIG. 7F may be a view (timing diagram) illustrating a read operation for reading data from a memory cell in which charges are stored in a storage node SN. First, referring to FIG. 7E, in a state in which the voltage of the bit line BL is set to the bit line reference voltage VCC/2, a first turn-on voltage VON1, lower than the first threshold voltage VTH1, may be applied to the word line WL. Accordingly, in a state in which the second transistor TR2 is turned off, only the first transistor TR1 may be turned on. Since the charges are not stored in the storage node SN, the voltage of the bit line BL may be decreased as illustrated in FIG. 7E.

Referring to FIG. 7F, in the state in which the voltage of the bit line BL is set to the bit line reference voltage VCC/2, the first turn-on voltage VON1, lower than the first threshold voltage VTH1, may be applied to the word line WL. Accordingly, in the state in which the second transistor TR2 is turned off, only the first transistor TR1 may be turned on. The voltage of the bit line BL may be increased as illustrated in FIG. 7F due to the charges stored in the storage node SN.

As described with reference to FIGS. 7A to 7F, in an example embodiment of the present disclosure, after executing the read operation for the memory cell, the voltage of the storage node SN may not be changed. Accordingly, as compared to a method of storing charge in a capacitor, the retention characteristics of the memory cell may be improved, and the performance of the semiconductor device may be improved by increasing an execution cycle of a refresh operation or reducing the number of executions; that is, a data retention time of the memory cell may be increased. Additionally, the multiply-accumulate (MAC) operation for implementing a neural network may be executed in the semiconductor device by changing an operation mode of the semiconductor device.

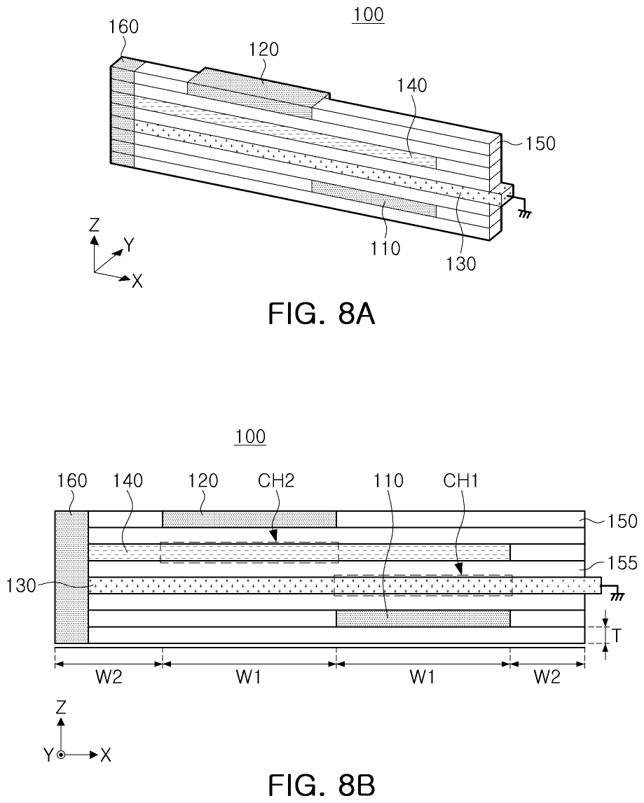

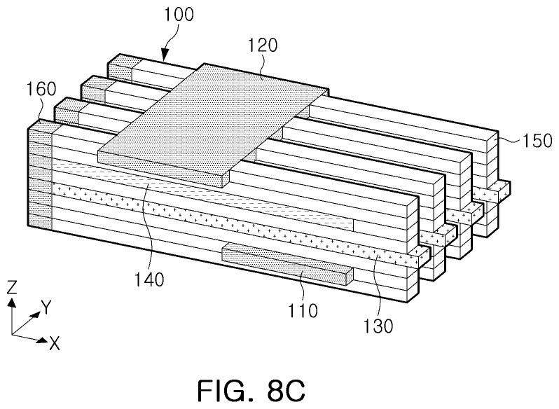

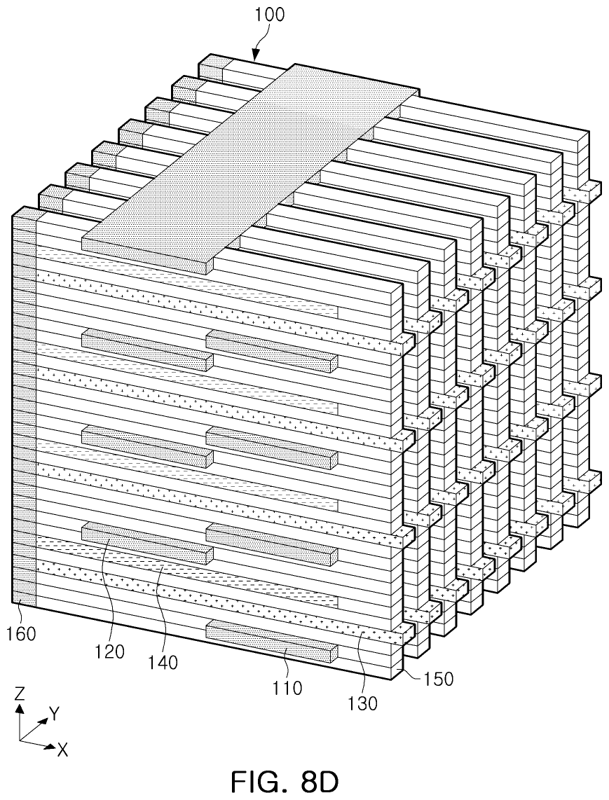

FIGS. 8A to 8D are schematic views simply illustrating a semiconductor device according to an example embodiment of the present disclosure.

A semiconductor device according to an example embodiment of the present disclosure may include a cell region in which a plurality of memory cells are disposed, and a peripheral circuit region in which circuits controlling the cell region are disposed. A plurality of unit structures providing a plurality of memory cells are disposed in the cell region, and, for example, one unit structure may correspond to one memory cell.

FIG. 8A may be a schematic perspective view illustrating one unit structure 100. Referring to FIG. 8A, the unit structure 100 may include a first gate electrode layer 110, a second gate electrode layer 120, a first semiconductor layer 130, a second semiconductor layer 140, a plurality of insulating layers 150, and a bit line electrode layer 160.

The first gate electrode layer 110 and the second gate electrode layer 120 may be disposed at different heights in a first direction (Z-axis direction) and may be separated from each other. As illustrated in FIG. 8C and FIG. 8D, each of the first gate electrode layer 110 and the second gate electrode layer 120 may extend in a second direction (Y-axis direction).

The first semiconductor layer 130 and the second semiconductor layer 140 may be formed of a semiconductor material such as silicon, and may be disposed between the first gate electrode layer 110 and the second gate electrode layer 120 in the first direction. The first semiconductor layer 130 and the second semiconductor layer 140 are disposed at different heights in the first direction, and may extend in a third direction (X-axis direction). The first semiconductor layer 130 and the second semiconductor layer 140 may be alternately stacked with a plurality of insulating layers 150 in the first direction. Accordingly, at least one of the plurality of insulating layers 150 may be disposed between the first semiconductor layer 130 and the first gate electrode layer 110 and between the second semiconductor layer 140 and the second gate electrode layer 120 in the first direction.

In an example embodiment, the first semiconductor layer 130 and the second semiconductor layer 140 may include the same semiconductor material, or may include different semiconductor materials. For example, in one or more embodiments, the first semiconductor layer 130 may be formed of silicon, and the second semiconductor layer 140 may be formed of a material different from silicon, such as Indium Gallium Zinc Oxide (IGZO).

The first gate electrode layer 110 and the first semiconductor layer 130 may provide a first transistor included in the memory cell, and the second gate electrode layer 120 and the second semiconductor layer 140 may provide a second transistor included in the memory cell. A channel and active regions of the first transistor may be provided by the first semiconductor layer 130, and a channel and active regions of the second transistor may be provided by the second semiconductor layer 140. As described above with reference to FIG. 2 and the like, one of the active regions of the first transistor may be connected to a reference node configured to supply a reference voltage. Accordingly, as illustrated in FIG. 8A, one end of the first semiconductor layer 130 may be connected to a reference node, for example, a ground node configured to supply a ground voltage.

The bit line electrode layer 160 functioning as a bit line from a circuit perspective may be commonly connected to the first semiconductor layer 130 and the second semiconductor layer 140 in the third direction. Accordingly, as described above with reference to FIG. 2, the first transistor and the second transistor included in one memory cell may be commonly connected to one bit line.

Each of the plurality of insulating layers 150 may be formed of silicon oxide or a high dielectric constant (high-K) material, although embodiments are not limited thereto. In an example embodiment, an insulating layer disposed between the first gate electrode layer 110 and the first semiconductor layer 130 in the first direction may provide a gate insulating layer of the first transistor, and an insulating layer disposed between the second gate electrode layer 120 and the second semiconductor layer 140 in the first direction may provide a gate insulating layer of the second transistor. Meanwhile, the insulating layer disposed between the first semiconductor layer 130 and the second semiconductor layer 140 in the first direction may be formed of a high-K material, or the like, and may provide a storage node capable of storing charges along with at least a portion of the second semiconductor layer 140.

Each of the first transistor and the second transistor may have different threshold voltages so as to be selectively turned on only in one of the write operation and the read operation. For example, the first transistor may be turned on in the write operation and turned off in the read operation, and the second transistor may be turned off in the write operation and turned on in the read operation. Alternatively, the first transistor may be turned off in the write operation and turned on in the read operation, and the second transistor may be turned on in the write operation and turned off in the read operation.

In this way, in order to implement the first transistor and the second transistor having different threshold voltages, the first semiconductor layer 130 and the second semiconductor layer 140 may be doped with impurities having different conductivity types or doped with different doping concentrations. Alternatively, the first gate electrode layer 110 and the second gate electrode layer 120 may be formed of conductive materials having different work functions. Alternatively, the insulating layer disposed between the first semiconductor layer 130 and the first gate electrode layer 110 may be formed of a material different from that of the insulating layer disposed between the second semiconductor layer 140 and the second gate electrode layer 120. According to an example embodiment, at least two or more of the material of the insulating layer, the materials of each of the gate electrode layers 110 and 120, and the conductivity type and concentration of the impurities doped into each of the semiconductor layers 130 and 140 may be different from each other.

FIG. 8B may be a schematic plan view of the unit structure 100 viewed from the second direction. Referring to FIG. 8B, the unit structure 100 may include a first gate electrode layer 110, a second gate electrode layer 120, a first semiconductor layer 130, a second semiconductor layer 140, a plurality of insulating layers 150, and a bit line electrode layer 160.

In the third direction (X-axis direction), a length of the second semiconductor layer 140 may be less than that of at least one of the insulating layers 150. For example, the length of the second semiconductor layer 140 in the third direction may be shorter than a length of a high-k layer 155 disposed between the first semiconductor layer 130 and the second semiconductor layer 140. In this case, as illustrated in FIG. 8B, at least one of the insulating layers 150 may be disposed on one side of the second semiconductor layer 140 defined on an opposite side of the bit line electrode layer 160 in the third direction. However, according to an example embodiment, the second semiconductor layer 140 may have substantially the same length as the first semiconductor layer 130 in the third direction.

Referring to FIG. 8B, the first gate electrode layer 110 and the second gate electrode layer 120 may have substantially the same first width W1 in the third direction. The first width W1 of each of the first gate electrode layer 110 and the second gate electrode layer 120 may vary depending on an overall size of the unit structure 100 and a degree of integration of the semiconductor device, and may be, for example, several tens of nanometers. Meanwhile, in the third direction, the first gate electrode layer 110 and the second gate electrode layer 120 may be disposed in different positions (i.e., offset from one another), and one side of the first gate electrode layer 110 may be disposed in the same position as one side of the second gate electrode layer 120 in the third direction. For example, the first gate electrode layer 110 may not overlap with the second gate electrode layer 120, in the first direction. As used herein, “an element A overlapping an element B in a direction X” (or similar language) means that there is at least one line that extends in the direction X and intersects both the elements A and B.

Each of the first gate electrode layer 110 and the second gate electrode layer 120 may be adjacent to the insulating layers 150 on both sides in the third direction. Referring to FIG. 8B, the insulating layer 150 disposed on one side of the first gate electrode layer 110 in the third direction may have a second width W2, and the insulating layer 150 disposed between the bit line electrode layer 160 and the second gate electrode layer 120 may also have a second width W2. In an example embodiment, the second width W2 may be several tens of nanometers, and for example, may be smaller than the first width W1.

Meanwhile, each of the first gate electrode layer 110, the second gate electrode layer 120, the first semiconductor layer 130, the second semiconductor layer 140, and the plurality of insulating layers 150 may have substantially the same thickness T in the first direction. In an example embodiment, the thickness T of each of the first gate electrode layer 110, the second gate electrode layer 120, the first semiconductor layer 130, the second semiconductor layer 140 and the plurality of insulating layers 150 may be 10 nanometers or less. The thickness T of each of the first semiconductor layer 130 and the second semiconductor layer 140 may be smaller than widths of each of the first semiconductor layer 130 and the second semiconductor layer 140 in the second direction.

As illustrated in FIG. 8B, a partial region of the first semiconductor layer 130 may provide a first channel CH1 of the first transistor, and a partial region of the second semiconductor layer 140 may provide a second channel CH2 of the second transistor. The first channel CH1 may be a partial region overlapping the first gate electrode layer 110 in the first direction, and the second channel CH2 may be a portion overlapping the second gate electrode layer 120 in the first direction. Accordingly, the first channel CH1 and the second channel CH2 may be defined in different positions in the third direction, so that the first channel CH1 and the second channel CH2 may be separated from each other, there minimizing an influence of on/off operations of the first transistor TR1 and the second transistor TR2 on each other.

Meanwhile, regions disposed on both sides of the first channel CH1 in the third direction in the first semiconductor layer 130 may provide first active regions (i.e., source/drain regions) of the first transistor, and regions disposed on both sides of the second channel CH2 in the third direction in the second semiconductor layer 140 may provide second active regions of the second transistor. For example, one of the first active regions and one of the second active regions may be connected to the bit line electrode layer 160.

Meanwhile, another of the first active regions may be connected to a ground node configured to supply a reference voltage, for example, a ground voltage. Another of the second active regions may provide a storage node configured to store or release charges by the write operation. For example, in the second semiconductor layer 140, the partial region overlapping the first gate electrode layer 110 in the first direction may provide a storage node along with the high-K layer 155.

Referring to FIG. 8C, a plurality of unit structures 100 arranged in the cell region may be arranged in the second direction. The plurality of unit structures 100 may be disposed in a single layer in the first direction, and the plurality of unit structures 100 arranged in the second direction may share the first gate electrode layer 110 and the second gate electrode layer 120. On the other hand, among the plurality of unit structures 100 arranged in the second direction, the first semiconductor layer 130, the second semiconductor layer 140 and the bit line electrode layer 160 may be separated from each other.

According to an example embodiment, the plurality of unit structures 100 may also be arranged in the third direction. The unit structures 100 disposed in the same position in the first direction and the second direction and arranged in the third direction may not share the first gate electrode layer 110 and the second gate electrode layer 120.

FIG. 8D may be a schematic perspective view illustrating a plurality of unit structures 100 arranged in a three-dimensional structure in the first to third directions in the cell region. Referring to FIG. 8D, a plurality of unit structures 100 stacked in the first direction and disposed in the same position in the second and third directions may share one bit line electrode layer 160. However, the plurality of unit structures 100 stacked in the first direction and disposed in the same position in the second and third directions may not share the first gate electrode layer 110 and the second gate electrode layer 120, thereby individually controlling the plurality of unit structures 100.

As illustrated in FIG. 8D, in a semiconductor device according to an example embodiment of the present disclosure, the unit structure 100 providing a memory cell may be implemented without a capacitor. Accordingly, as compared to a conventional structure in which capacitors and transistors are stacked in the first direction, the degree of integration of the semiconductor device may be improved by disposing the unit structures 100 in a three-dimensional structure. Additionally, the transistors turned on in the write operation and the transistors turned on in the read operation may be separated from each other in one memory cell, thereby improving both the retention characteristics and the write operation characteristics of the memory cell.

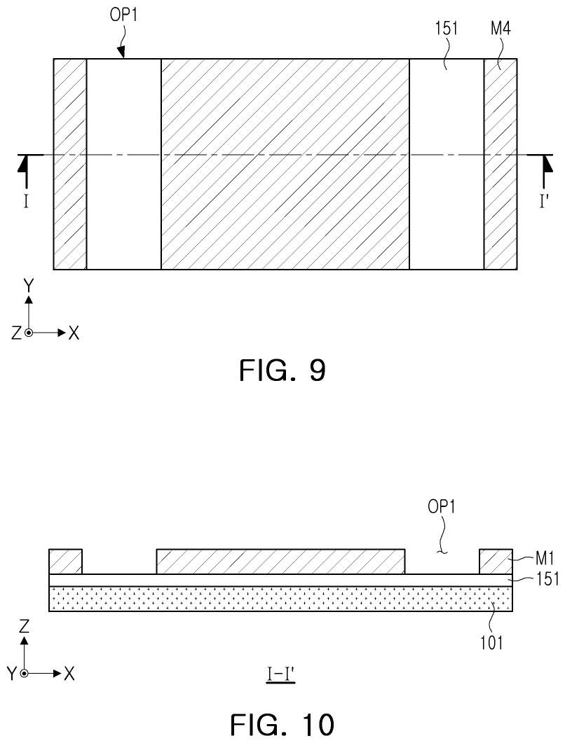

FIGS. 9 to 58 are schematic drawings provided to explain intermediate processes in a method of manufacturing a semiconductor device according to an example embodiment of the present disclosure.

First, referring to FIGS. 9 and 10, a first insulating layer 151 and a first mask layer M1 may be formed on a substrate 101, in the first direction (Z-axis direction), perpendicular to an upper surface of the substrate 101 including the semiconductor material. FIG. 10 is a schematic cross-sectional view taken along line I-I′ in FIG. 9, and at least a partial region of the first insulating layer 151 may be exposed in first opening regions OP1 of the first mask layer M1. The term “exposed” (or “exposing,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device. The first insulating layer 151 may be formed of silicon oxide, or the like.

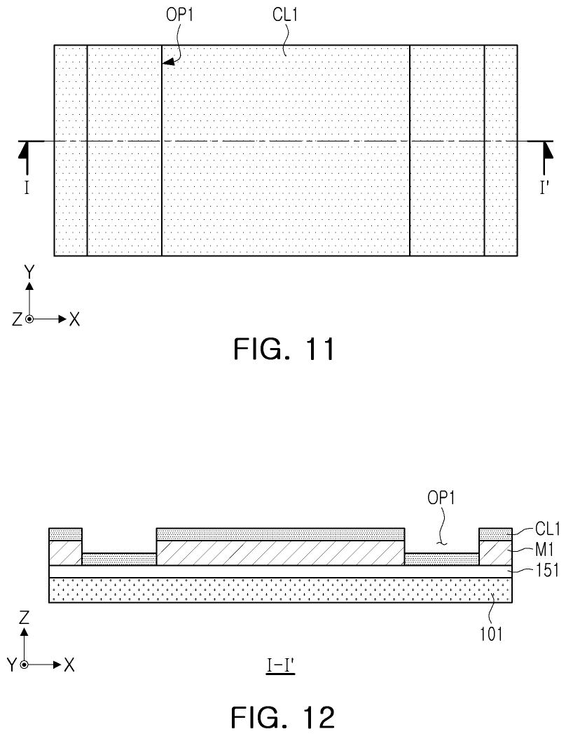

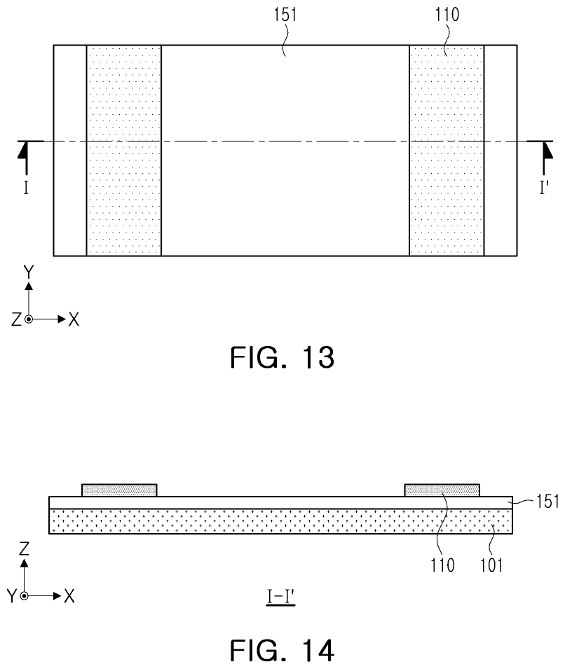

Referring to FIGS. 11 and 12, a first conductive layer CL1 may be formed of a conductive material on the first mask layer M1. FIG. 11 is a schematic plan view and FIG. 12 is a schematic cross-sectional view taken along line I-I′ in FIG. 11. As illustrated in FIGS. 11 and 12, the first conductive layer CL1 may be formed on the first insulating layer 151 in the first opening regions OP1. Then, as illustrated in FIGS. 13 and 14, where FIG. 13 is a schematic plan view and FIG. 14 is a schematic cross-sectional view taken along line I-I′ in FIG. 13, the first mask layer M1 may be removed, along with portions of the first conductive layer CL1 on the first mask layer M1, to form the first gate electrode layer 110. The first gate electrode layer 110 may extend in the second direction (Y-axis direction).

The first gate electrode layer 110 may be formed in a different manner from the method described with reference to FIGS. 11 to 14. For example, the first conductive layer CL1 may be first formed on the first insulating layer 151, and a mask layer may be formed on the first conductive layer CL1 so as to cover only a position corresponding to the first gate electrode layer 110, and then the first conductive layer CL1 may be removed from a region exposed by the mask layer, thereby forming the first gate electrode layer 110.

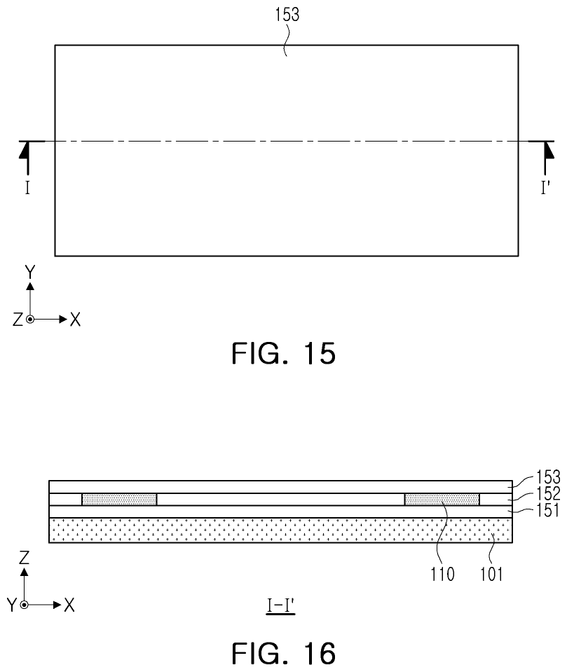

When the first gate electrode layer 110 is formed, as illustrated in FIGS. 15 and 16, where FIG. 15 is a schematic plan view and FIG. 16 is a schematic cross-sectional view taken along line I-I′ in FIG. 15, a second insulating layer 152 and a third insulating layer 153 may be formed. The second insulating layer 152 may be formed at the same height as that of the first gate electrode layer 110 in the first direction (i.e., the second insulating layer 152 and the first gate electrode layer 110 may be coplanar), and may be formed between the first gate electrode layers 110 in the third direction (X-axis direction). The third insulating layer 153 may be formed on the first gate electrode layer 110 and the second insulating layer 152. The second insulating layer 152 and the third insulating layer 153 may be formed of the same material as the first insulating layer 151, although embodiments are not limited thereto.

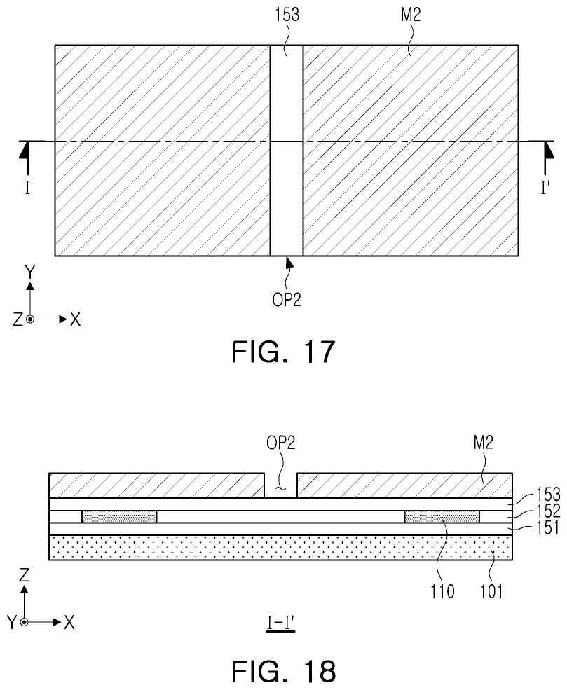

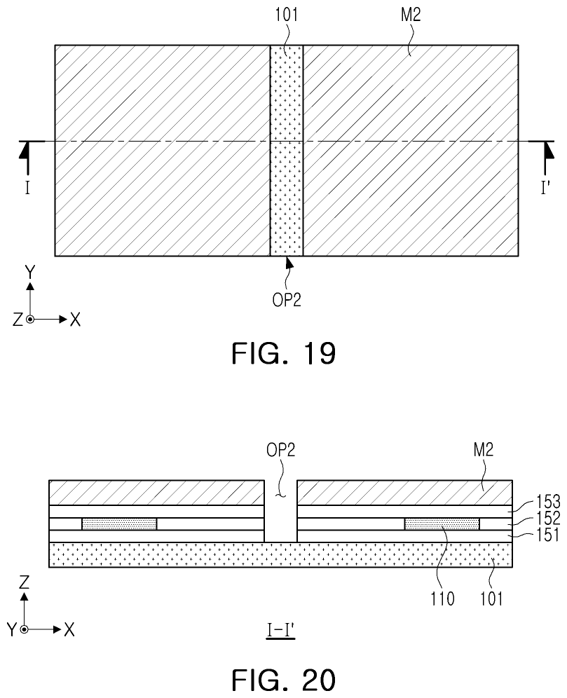

Next, referring to FIGS. 17 and 18, where FIG. 17 is a schematic plan view and FIG. 18 is a schematic cross-sectional view taken along line I-I′ in FIG. 17, a second mask layer M2 may be formed on the third insulating layer 153. The second mask layer M2 may include a second opening region OP2, and the second opening region OP2 may extend in the second direction (Y-axis direction), and may be formed between the first gate electrode layers 110 in the third direction (X-axis direction). Then, as illustrated in FIGS. 19 and 20, where FIG. 19 is a schematic plan view and FIG. 20 is a schematic cross-sectional view taken along line I-I′ in FIG. 19, the first to third insulating layers 151 to 153 may be removed from the second opening region OP2 to expose a partial region of the substrate 101.

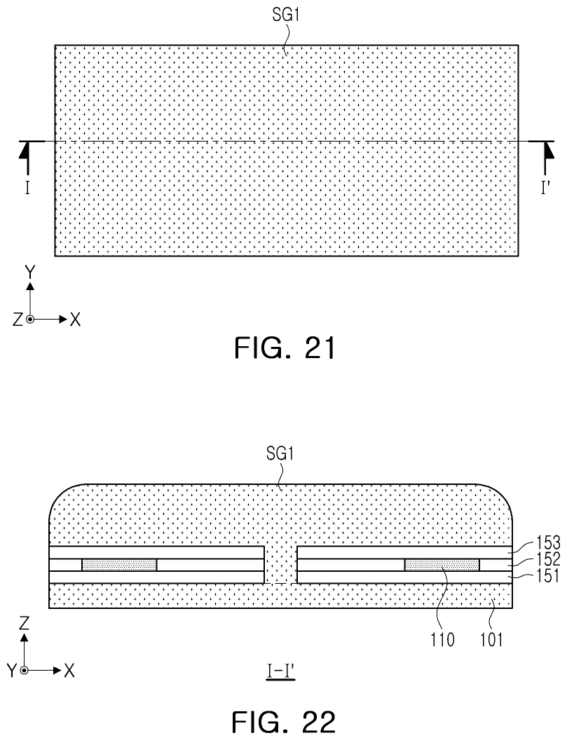

Referring to FIGS. 21 and 22, where FIG. 21 is a schematic plan view and FIG. 22 is a schematic cross-sectional view taken along line I-I′ in FIG. 21, after removing the second mask layer M2, a growth process may be performed using the partial region of the substrate 101 exposed in the second opening region OP2 as a seed. By the growth process starting from the partial region of the substrate 101 exposed in the second opening region OP2, a first semiconductor growth layer SG1 extending from the substrate 101 may be formed on the third insulating layer 153.

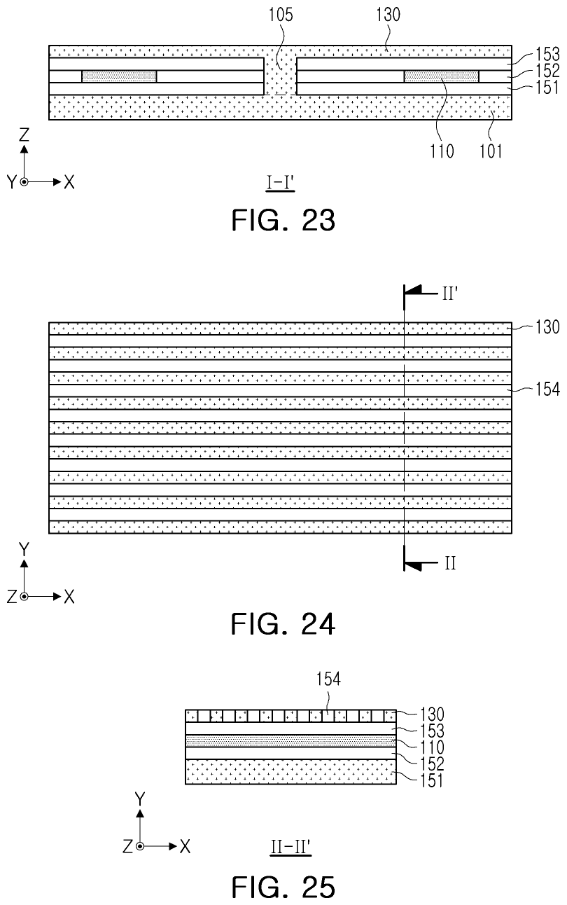

Next, referring to FIGS. 23 to 25, where FIG. 23 is a schematic cross-sectional view taken along line I-I′ in FIG. 21, FIG. 24 is a schematic plan view, and FIG. 25 is a schematic cross-sectional view taken along line II-II′ in FIG. 24, an etching process may be performed to remove and pattern a portion of the first semiconductor growth layer SG1. In an example embodiment, a Chemical Mechanical Polishing (CMP) process, or the like, may be performed first to remove a portion of the first semiconductor growth layer SG1 and planarize the portion thereof, and then the planarized first semiconductor growth layer SG1 may be patterned to form a plurality of first semiconductor layers 130. The first semiconductor layers 130 may be arranged in the second direction (Y-axis direction) and may extend in the third direction (X-axis direction).

Referring to FIGS. 24 and 25, the first semiconductor layers 130 may be alternately arranged with fourth insulating layers 154 in the second direction (Y-axis direction). The first semiconductor layers 130 may be connected to the substrate 101 by a vertical semiconductor layer 105 filling the second opening region OP2. The term “connected” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items.

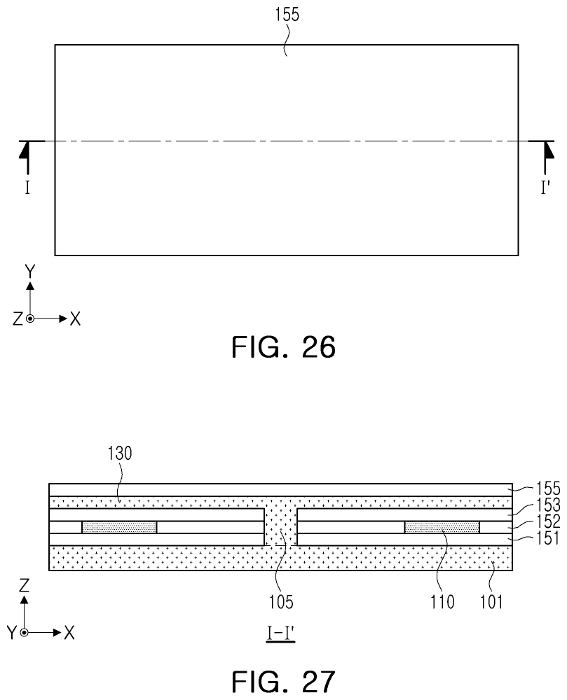

Next, referring to FIGS. 26 and 27, where FIG. 26 is a schematic plan view and FIG. 27 is a schematic cross-sectional view taken along line I-I′ in FIG. 26, a fifth insulating layer 155 may be formed on the first semiconductor layers 130 and the fourth insulating layers 154. The fifth insulating layer 155 may be formed of the same material as the first to fourth insulating layers 151 to 154, for example, silicon oxide. Alternatively, according to an example embodiment, the fifth insulating layer 155 may be formed of a high-K material different from that of the first to fourth insulating layers 151 to 154. For example, the fifth insulating layer 155 may be formed of a high-k material such as Al₂O₃, Ta₂O₅, ZrO₂, HfO₂, or TiO₂.

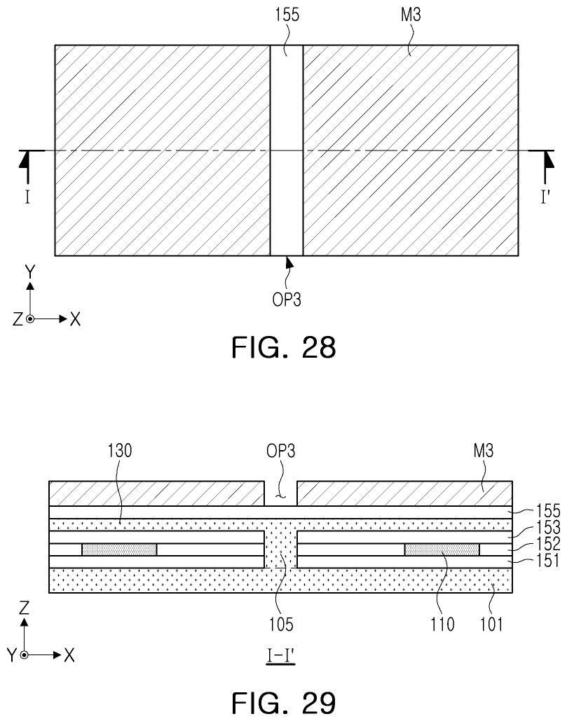

Referring to FIGS. 28 and 29, where FIG. 28 is a schematic plan view and FIG. 29 is a schematic cross-sectional view taken along line I-I′ in FIG. 28, when the fifth insulating layer 155 is formed, a third mask layer M3 having a third opening region OP3 may be formed on the fifth insulating layer 155. In an example embodiment, the third mask layer M3 may have substantially the same shape as the second mask layer M2 described above.

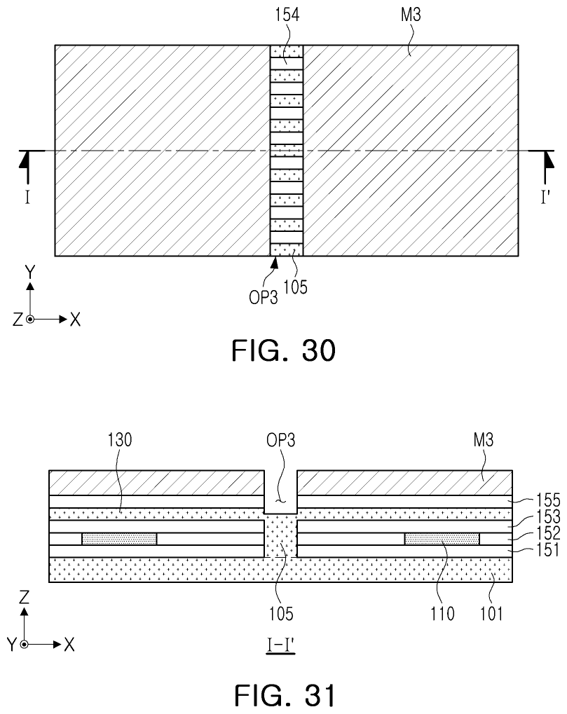

In the third opening region OP3, a partial portion of the fifth insulating layer 155 may be exposed, and as illustrated in FIGS. 30 and 31, where FIG. 30 is a schematic plan view and FIG. 31 is a schematic cross-sectional view taken along line I-I′ in FIG. 30, an etching process may be performed in the third opening region OP3 to expose the vertical semiconductor layer 105 and the fourth insulating layers 154 to the outside. According to an example embodiment, the etching process may be performed until the substrate 101 is exposed in the third opening region OP3.

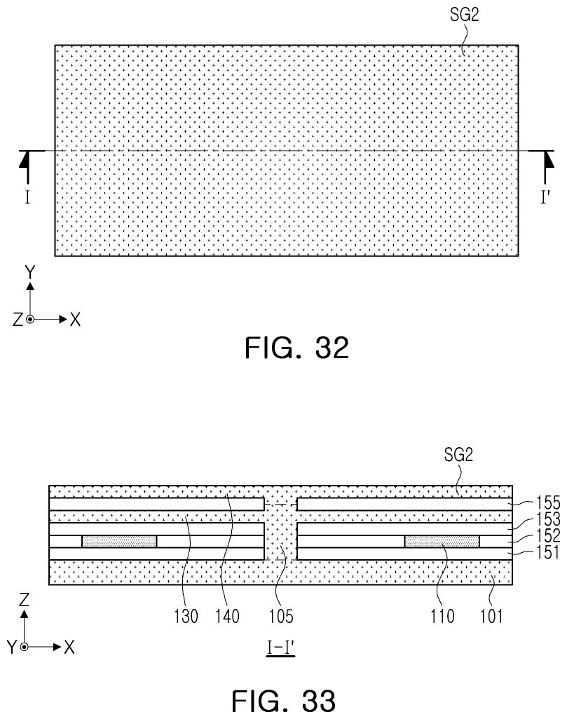

Referring to FIGS. 32 and 33, where FIG. 32 is a schematic plan view and FIG. 33 is a schematic cross-sectional view taken along line I-I′ in FIG. 32, after the third mask layer M3 is removed, a growth process using the vertical semiconductor layer 105 exposed in the third opening region OP3 as a seed may be performed. By the growth process starting from the third opening region OP3, a second semiconductor growth layer SG2 extending from the vertical semiconductor layer 105 may be formed on the fifth insulating layer 155. When the growth process of forming the second semiconductor growth layer SG2 is completed, a CMP process, or the like, of planarizing the second semiconductor growth layer SG2 may be performed.

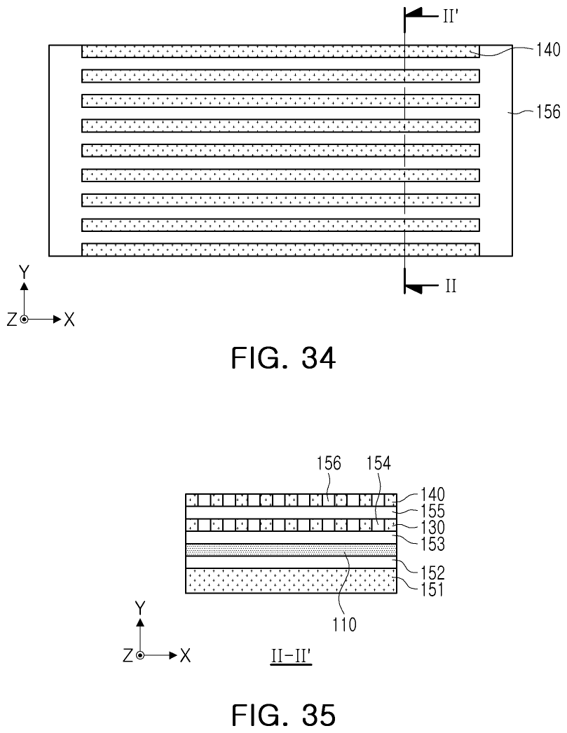

Referring to FIGS. 34 and 35, where FIG. 34 is a schematic plan view and FIG. 35 is a schematic cross-sectional view taken along line II-II′ in FIG. 34, the second semiconductor growth layer SG2 (see FIG. 33) may be patterned to form second semiconductor layers 140, and a sixth insulating layer 156 may be formed between the second semiconductor layers 140. The second semiconductor layers 140 may be arranged in the second direction (Y-axis direction) and may extend in the third direction (X-axis direction), similarly to the first semiconductor layers 130. The second semiconductor layers 140 may be disposed in the same position as the first semiconductor layers 130 in the second direction, and therefore, as illustrated in FIG. 35, the first semiconductor layers 130 and the second semiconductor layers 140 may overlap each other in the first direction (Z-axis direction).

In an example embodiment, the second semiconductor layer 140 may be shorter than the first semiconductor layer 130 in the third direction. Referring to FIGS. 34 and 35, the sixth insulating layer 156 may be disposed on both sides of the second semiconductor layer 140 in the third direction.

In an example embodiment illustrated in FIGS. 34 and 35, each of the first semiconductor layers 130 and the second semiconductor layers 140 may have substantially the same width in the second direction. However, according to an example embodiment, maximum widths of each of the second semiconductor layers 140 in the second direction may be greater than maximum widths of each of the first semiconductor layers 130. For example, in a region providing the storage node, the widths of each of the second semiconductor layers 140 may be greater than the widths of each of the first semiconductor layers 130.

Meanwhile, according to an example embodiment, the second semiconductor layer 140 may be formed of a different material from that of the first semiconductor layer 130. For example, the first semiconductor layer 130 may be formed of silicon as described above, and the second semiconductor layer 140 may be formed of a different material from silicon, such as Indium Gallium Zinc Oxide (IGZO). When the second semiconductor layer 140 is formed of a different material from silicon, the second semiconductor layer 140 may be formed in a deposition process instead of the growth process using the vertical semiconductor layer 105 as a seed as described above.

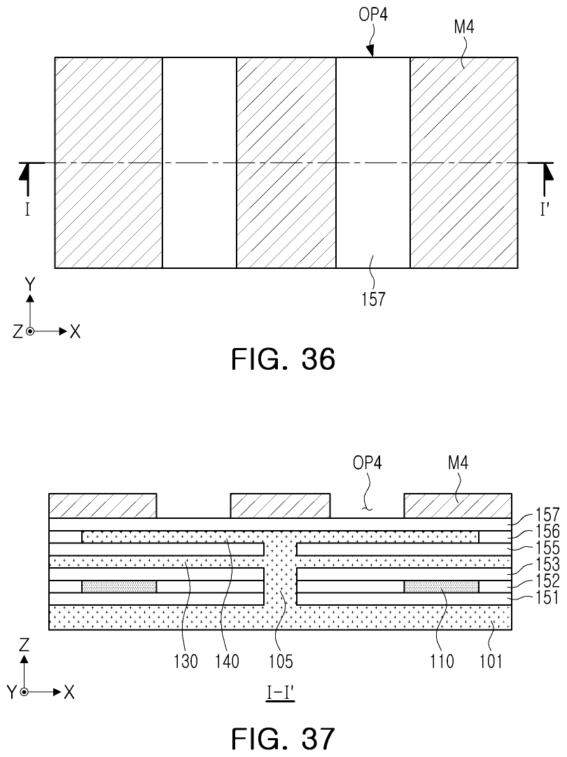

Referring to FIGS. 36 and 37, where FIG. 36 is a schematic plan view and FIG. 37 is a schematic cross-sectional view taken along line I-I′ in FIG. 36, a seventh insulating layer 157 may be formed on the second semiconductor layers 140 and the sixth insulating layer 156, and a fourth mask layer M4 may be formed on the seventh insulating layer 157. The fourth mask layer M4 may include fourth opening regions OP4, and the fourth opening regions OP4 may extend in the second direction (Y-axis direction) as illustrated in FIG. 36.

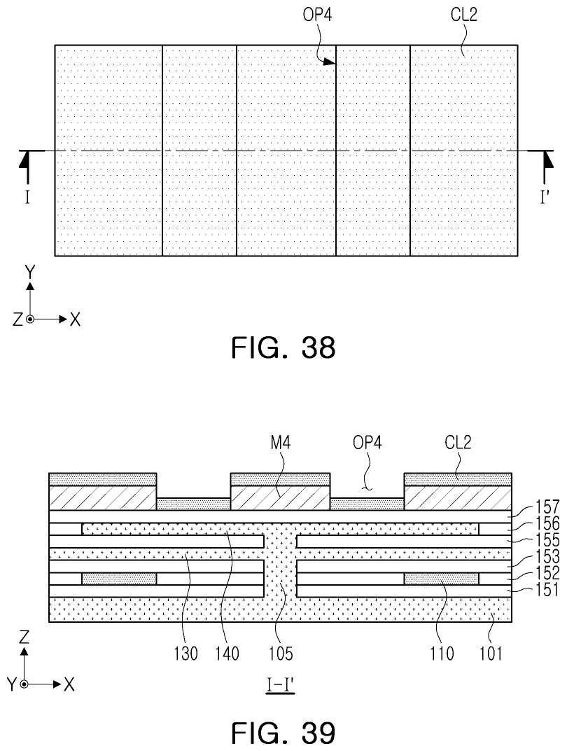

Next, referring to FIGS. 38 and 39, where FIG. 38 is a schematic plan view and FIG. 39 is a schematic cross-sectional view taken along line I-I′ in FIG. 38, a second conductive layer CL2 may be formed on the fourth mask layer M4 using a conductive material. In an example embodiment, the second conductive layer CL2 may be formed of the same material as the first conductive layer CL1 described above with reference to FIGS. 11 and 12 or a different material therefrom. When the second conductive layer CL2 is formed of the different material from the first conductive layer CL1, the second conductive layer CL2 and the first conductive layer CL1 may be formed of materials having different work functions.

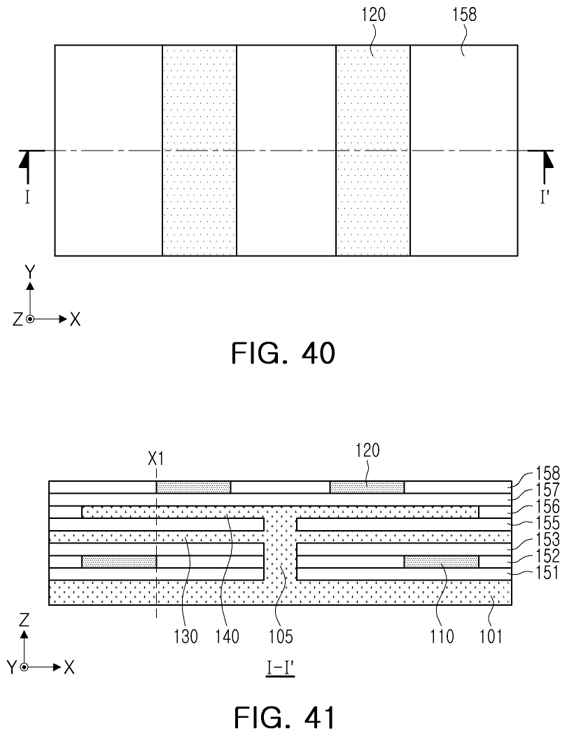

The second conductive layer CL2 may be formed on the fourth mask layer M4 and on the seventh insulating layer 157 exposed in the fourth opening regions OP4, and as illustrated in FIGS. 40 and 41, where FIG. 40 is a schematic plan view and FIG. 41 is a schematic cross-sectional view taken along line I-I′ in FIG. 40, the second gate electrode layer 120 may be formed by removing the fourth mask layer M4, along with portions of the second conductive layer CL2 on the fourth mask layer M4. The second gate electrode layer 120 may extend in the second direction (Y-axis direction), and may be formed in a position different from the first gate electrode layer 110 in the third direction (X-axis direction). Referring to FIG. 41, one side of the first gate electrode layer 110 may be disposed in the same first position (X1) as one side of the second gate electrode layer 120 in the third direction. An eighth insulating layer 158 may be formed around the second gate electrode layer 120.

According to example embodiments, the second gate electrode layer 120 may be formed in a different manner from that described with reference to FIGS. 38 to 41. For example, the second conductive layer CL2 may be first formed on the seventh insulating layer 157, and a mask layer covering only a region corresponding to the second gate electrode layer 120 may be formed on the second conductive layer CL2, and then, the second conductive layer CL2 may be removed from the exposed region, thereby forming the second gate electrode layer 120.

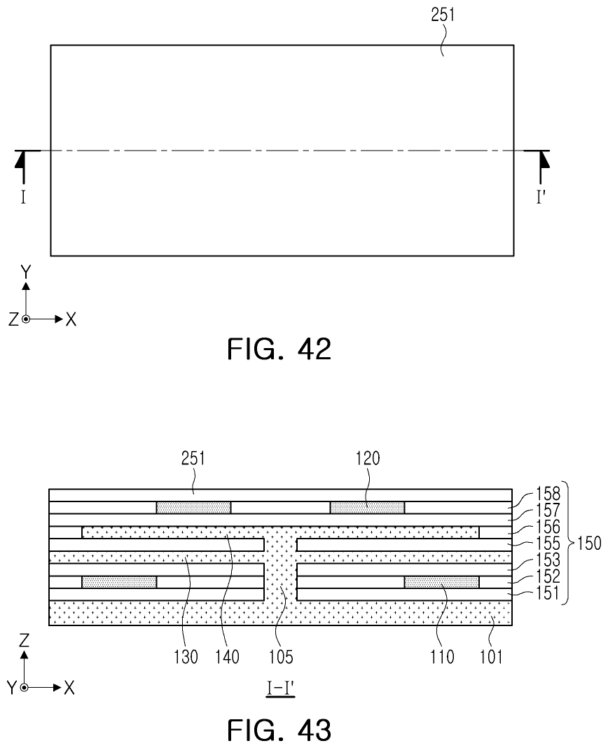

The first gate electrode layer 110, the second gate electrode layer 120, the first semiconductor layer 130, the second semiconductor layer 140, and the plurality of insulating layers (151 to 158, collectively 150) may be included in a first unit structure providing the first memory cell. Referring to FIGS. 42 and 43, where FIG. 42 is a schematic plan view and FIG. 43 is a schematic cross-sectional view taken along line I-I′ in FIG. 42, when the first unit structure is formed, a first insulating layer 251 may be formed on the second gate electrode layer 120 so as to form a second unit structure stacked with the first unit structure in the first direction and configured to provide a second memory cell.

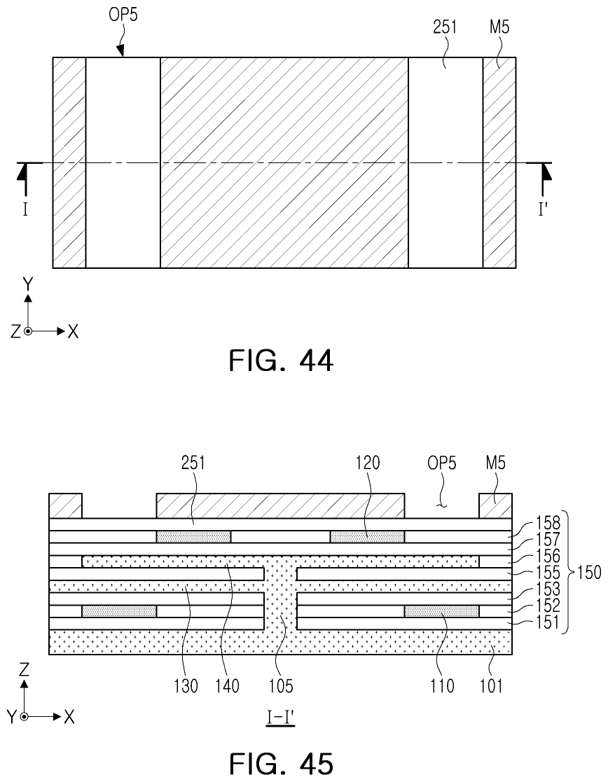

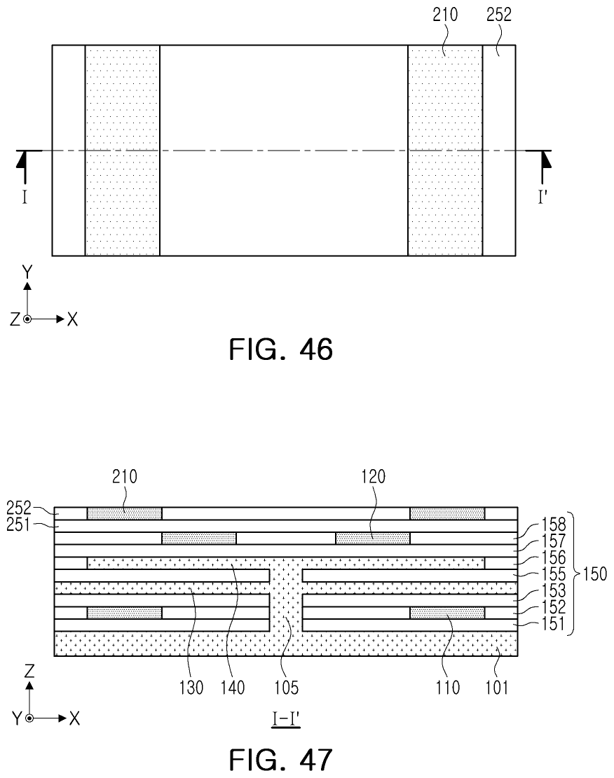

Referring to FIGS. 44 and 45, where FIG. 44 is a schematic plan view and FIG. 45 is a schematic cross-sectional view taken along line I-I′ in FIG. 44, a fifth mask layer M5 may be formed on the first insulating layer 251. The fifth mask layer M5 may include fifth opening regions OP5, and a portion of the first insulating layer 251 may be exposed to the outside in the fifth opening regions OP5. Then, a conductive layer filling the fifth opening regions OP5 may be formed and the fifth mask layer M5 may be removed to form a first gate electrode layer 210, as illustrated in FIGS. 46 and 47, where FIG. 46 is a schematic plan view and FIG. 47 is a schematic cross-sectional view taken along line I-I′ in FIG. 46. The term “filling” (or “fill,” or like terms) is intended to refer to either completely filling a defined space (e.g., the fifth opening regions OP5) or partially filling the defined space; that is, the defined space need not be entirely filled but may, for example, be partially filled or have voids or other spaces throughout. A second insulating layer 252 may be formed around the first gate electrode layer 210.

The first gate electrode layer 210 may extend in the second direction (Y-axis direction), and may be formed in substantially the same position as the first gate electrode layer 110 of the first unit structure in the third direction (X-axis direction). Accordingly, the first gate electrode layer 210 may overlap the first gate electrode layer 110 of the first unit structure in the first direction (Z-axis direction).

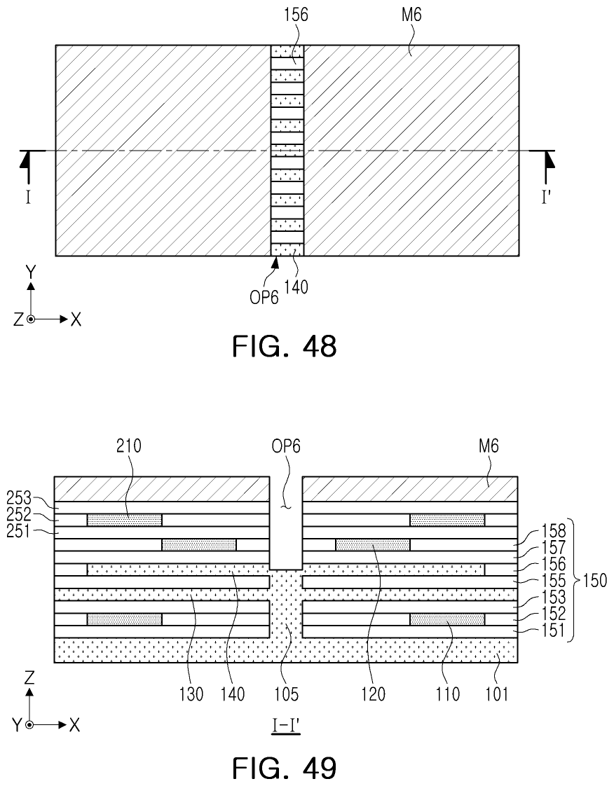

Referring to FIGS. 48 and 49, where FIG. 48 is a schematic plan view and FIG. 49 is a schematic cross-sectional view taken along line I-I′ in FIG. 48, a sixth mask layer M6 having a sixth opening region OP6 may be formed on the first gate electrode layer 210 and the second insulating layer 252. The sixth opening region OP6 may be formed on the vertical semiconductor layer 105 in the first direction (Z-axis direction). Accordingly, as illustrated in FIG. 49, by performing an etching process in the sixth opening region OP6, the vertical semiconductor layer 105 may be exposed to the outside.

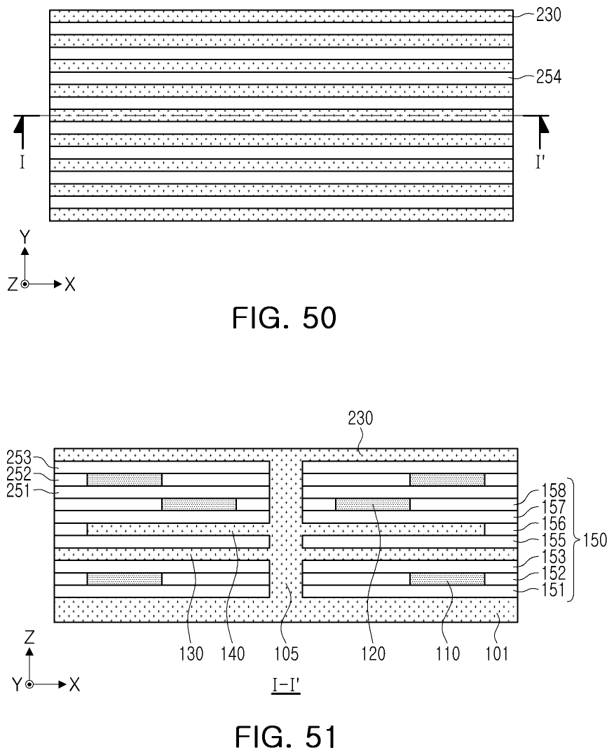

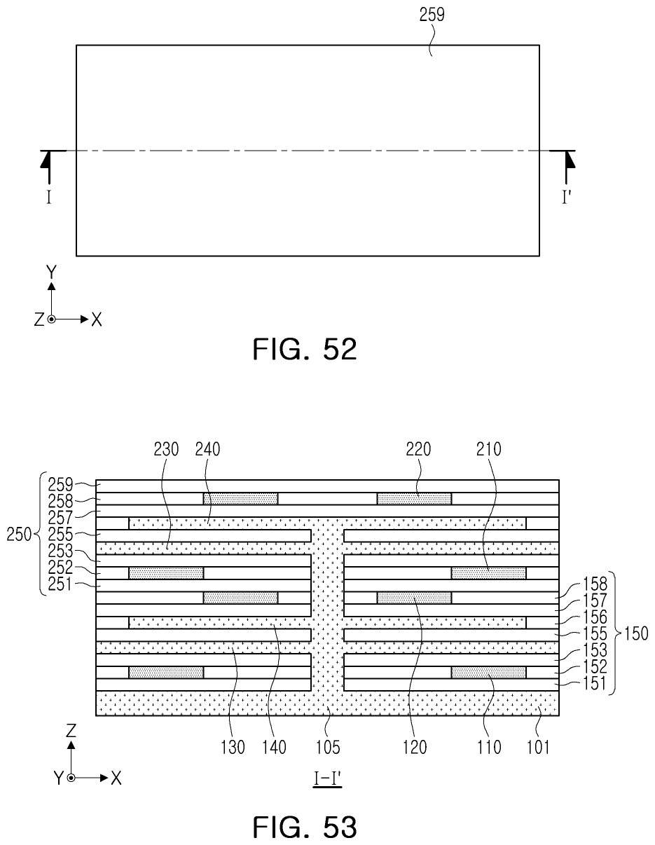

When the vertical semiconductor layer 105 is exposed, the sixth mask layer M6 may be removed, and then, a growth process using the vertical semiconductor layer 105 as a seed may be performed to form a third semiconductor growth layer SG3, as illustrated in FIGS. 50 and 51, where FIG. 50 is a schematic plan view and FIG. 51 is a schematic cross-sectional view taken along line I-I′ in FIG. 50. Then, by performing the process described with reference to FIGS. 21 to 41, as illustrated in FIGS. 52 and 53, a plurality of first semiconductor layers 230, a plurality of second semiconductor layers 240, a second gate electrode layer 220, and a plurality of insulating layers (251 to 259, collectively 250) may be formed. The first gate electrode layer 210, the second gate electrode layer 220, the first semiconductor layer 230, the second semiconductor layer 240, and the plurality of insulating layers 250 may be included in a second unit structure providing a second memory cell. Then, according to an example embodiment, a third unit structure stacked with the second unit structure in the first direction (Z-axis direction) and configured to provide a third memory cell may be further formed.

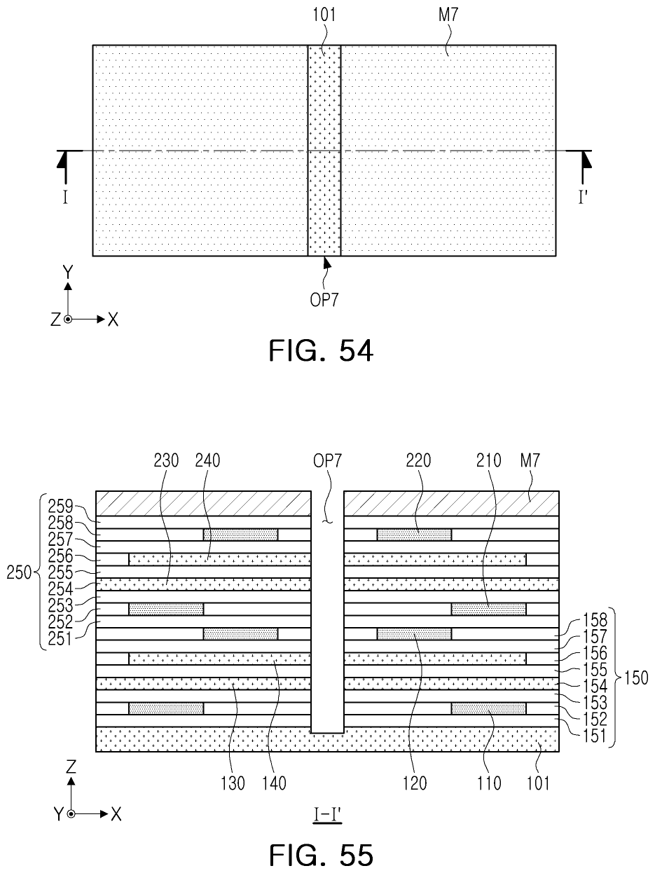

Referring to FIGS. 54 and 55, where FIG. 54 is a schematic plan view and FIG. 55 is a schematic cross-sectional view taken along line I-I′ in FIG. 54, a seventh mask layer M7 may be formed on a ninth insulating layer 259 disposed in an uppermost portion of the second unit structure. The seventh mask layer M7 may include a seventh opening region OP7, and the seventh opening region OP7 may be disposed on the vertical semiconductor layer 105. By performing an etching process in the seventh opening region OP7, a partial region of the substrate 101 may be exposed to the outside, as illustrated in FIGS. 54 and 55, and the vertical semiconductor layer 105 may be removed.

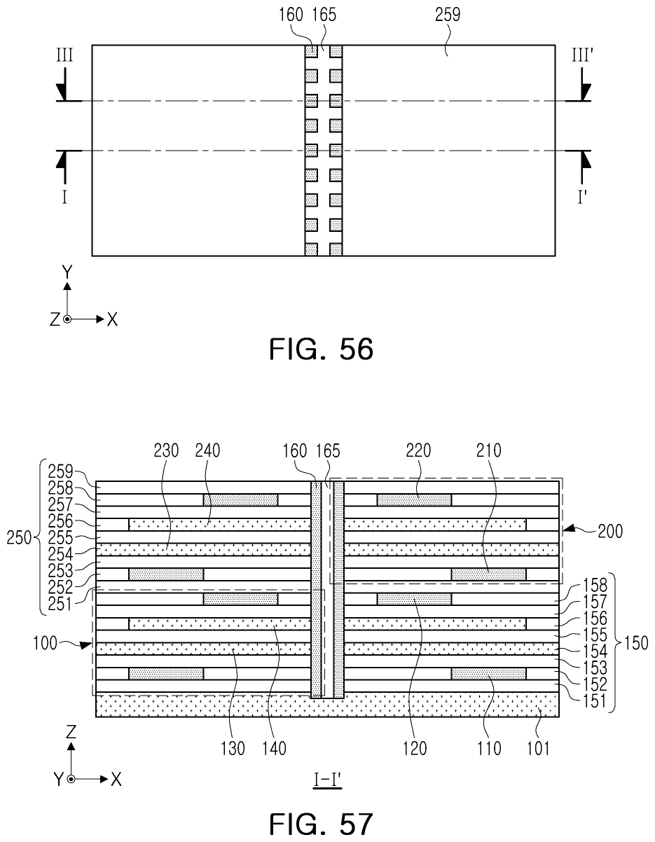

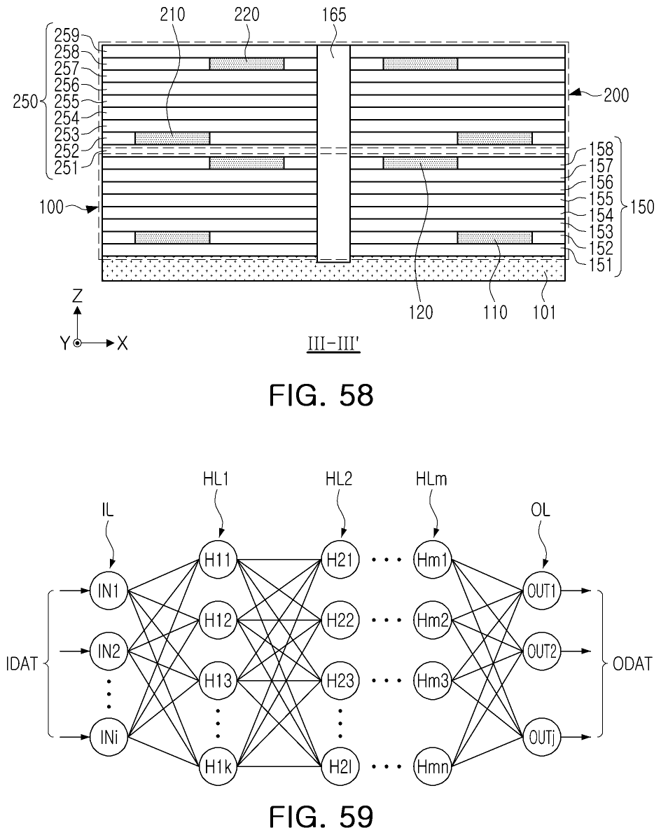

Next, referring to FIGS. 56 to 58, where FIG. 56 is a schematic plan view, FIG. 57 is a schematic cross-sectional view taken along line I-I′ in FIG. 56, and FIG. 58 is a schematic cross-sectional view taken along line III-III′ in FIG. 56, a plurality of bit line electrode layers 160 and a bit line insulating layer 165 may be formed in the seventh opening region OP7. The plurality of bit line electrode layers 160 may extend in the first direction (Z-axis direction), and may be arranged in the second direction (Y-axis direction) and the third direction (X-axis direction).

One bit line electrode layer 160 may be connected to the first semiconductor layer 130 and the second semiconductor layer 140 included in one of the first unit structures 100 in the third direction, and the first semiconductor layer 230 and the second semiconductor layer 240 included in one of a plurality of second unit structures 200. Accordingly, the first unit structure 100 and the second unit structure 200 stacked in the first direction and disposed in the same position in the second direction and the third direction may share one bit line electrode layer 160.

Referring to FIG. 58, the plurality of bit line electrode layers 160 may be disposed in the same position as the first semiconductor layers 130 and 230 and the second semiconductor layers 140 and 240 in the second direction. Accordingly, as illustrated in FIG. 58, the bit line insulating layer 165 may be in contact with the plurality of insulating layers 150 and 250 in the third direction.

By the method described with reference to FIGS. 9 to 58, the plurality of unit structures 100 and 200 disposed and stacked in the first to third directions may be formed. Each of the plurality of unit structures 100 and 200 may provide one memory cell, and the memory cell may have a structure including a first transistor and a second transistor without a capacitor. An operation of writing data may be performed in a manner of storing charges in the storage node or removing charges from the storage node. The storage node may be provided by partial regions of the second semiconductor layer 140 and 240, and the fifth insulating layers 155 and 255 formed of a high-K material or the like.

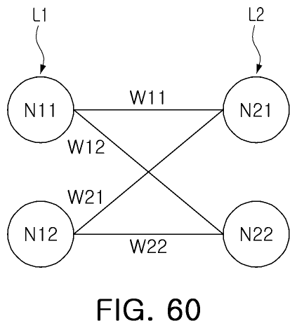

FIGS. 59 and 60 are views illustrating a neural network that may be implemented with a semiconductor device according to an example embodiment of the present disclosure.

Referring to FIG. 59, the neural network may include an input layer IL, a plurality of hidden layers HL1, HL2, to HLm (where m is a natural number), and an output layer OL. The input layer IL may include i (where i is a natural number) input nodes IN1 to INi, and, for example, input data IDAT in the form of a vector having a length of i may be input to each input node.

The input data IDAT may be input to a hidden layer including m hidden layers HL1 to HLm, and each of the hidden layers HL1 to HLm may include hidden nodes. For example, a first hidden layer HL1 may include k (where k is a natural number) hidden nodes H11 to Hlk, and a mth hidden layer HLm may include n hidden nodes Hm1 to Hmn (where n is a natural number).

In an example embodiment illustrated in FIG. 59, the number of hidden nodes included in each of the hidden layers HL1 to HLm may be variously determined. For example, at least a first subset of the hidden layers HL1 to HLm may include the same number of hidden nodes, and at least a second subset of the hidden layers HL1 to HLm may include different numbers of hidden nodes.

The output layer OL may include j (where j is a natural number) output nodes OUT1 to OUTj. For example, the output layer OL may output results (e.g., scores or class scores) for each class as output data ODAT for input data IDAT.

In the neural network illustrated in FIG. 59, weights may be allocated to a connection path between nodes drawn as straight lines between two nodes. Nodes included in one layer of the hidden layers HL1 to HLm may not be connected to each other, and nodes included in different layers may be entirely or partially connected.

In the neural network according to an example embodiment illustrated in FIG. 59, each node may be completely connected to each other. Each node may receive outputs of previous nodes, perform calculations, and output calculation results to following nodes. In this case, each node may apply the received values to a specific function, for example, a nonlinear function, thus calculating values to be output.

In an example embodiment, the weights allocated to the connection paths connecting the nodes included in the neural network may be determined using a data set whose correct answers are already known. The data set used to determine the weights may be training data, and a training task for adjusting the weights allocated to the connection path between the nodes in the neural network may be performed using the training data.

Each of the plurality of memory cells included in the semiconductor device according to an example embodiment of the present disclosure may include a first transistor and a second transistor, and one of the first transistor and the second transistor may be turned on only in the write operation, and the other thereof may be turned on only in the read operation. Additionally, data may be written to the memory cell in a manner of storing or removing charges in the storage node, and the data written to the memory cell may not be lost after executing the read operation.

Accordingly, the semiconductor device according to an example embodiment of the present disclosure may be used to efficiently implement an operation required for an inference task based on a neural network. First, the weights allocated to the connection path of the neural network for which learning has been completed may be stored in the memory cells. The weights allocated to the connection paths connecting two or more previous nodes to one following node may be stored in the memory cells connected to one bit line. Since the memory cells connected to one bit line are connected to different word lines, voltages corresponding to the values of two or more previous nodes may be input to the word lines, thereby obtaining an operation result corresponding to one following node through one bit line. Hereinafter, this will be described in more detail with reference to FIG. 60.

FIG. 60 is a view illustrating a connection relationship of some nodes that may be included in a neural network. Referring to FIG. 60, a first layer L1 may include first and second nodes N11 and N12, and a second layer L2 may include first and second nodes N21 and N22. The first layer L1 and the second layer L2 may be completely connected to each other, and weights W11, W12, W21 and W22 may be allocated to respective connection paths connecting the nodes N11, N12, N21 and N22 of the first layer L1 and the second layer L2. Values input to each of the first node N21 and the second node N22 of the second layer L2 may be defined as in the following mathematical expression 1.

$$N 21 = N 11 * W 11 + N 12 * W 21 \\ N 22 = N 11 * W 12 + N 12 * W 22 \qquad Mathematical Expression 1$$

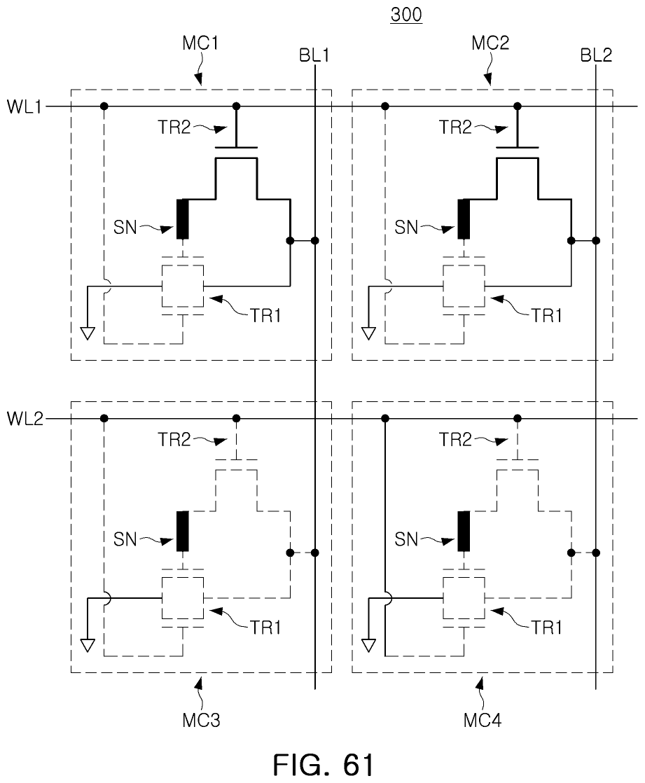

Hereinafter, with reference to FIGS. 61 to 63, a semiconductor device supporting operations executed in the nodes N11, N12, N21 and N22 illustrated in FIG. 60 will be described.

FIGS. 61 to 63 are schematic circuit diagrams conceptually illustrating an operation of at least a portion of a semiconductor device according to an example embodiment of the present disclosure.

Referring to FIGS. 61 to 63, a semiconductor device 300 according to an example embodiment of the present disclosure may include memory cells MC1 to MC4, and the memory cells MC1 to MC4 may be connected to word lines WL1 and WL2 and bit lines BL1 and BL2. Each of the memory cells MC1 to MC4 may include a first transistor TR1 and a second transistor TR2, and the first transistor TR1 and the second transistor TR2 may have different threshold voltages.

For example, the first transistor TR1 may be an NMOS transistor, and the second transistor TR2 may be a PMOS transistor. Accordingly, depending on voltages input to each of the word lines WL1 and WL2, both the first transistor TR1 and the second transistor TR2 in each of the memory cells MC1 to MC4 may be turned off, only the first transistor TR1 may be turned on, or only the second transistor TR2 may be turned on.

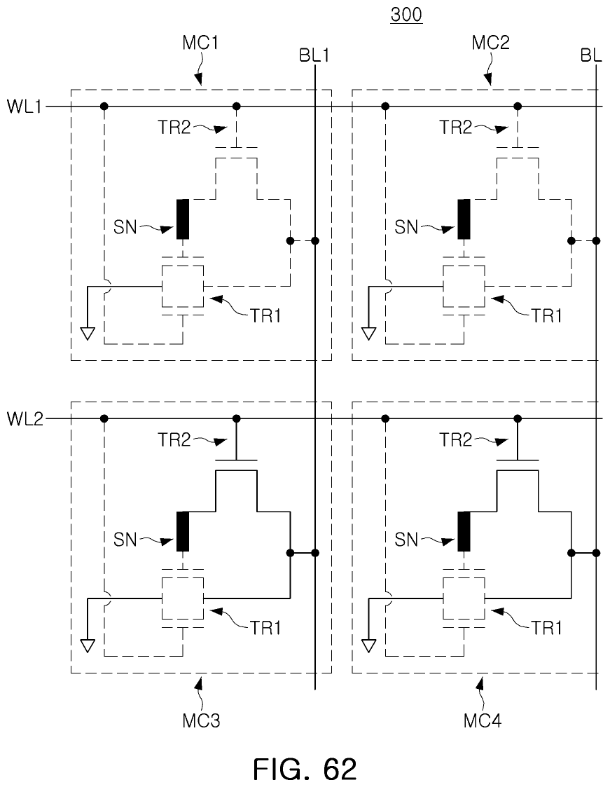

First, referring to FIGS. 61 and 62, a write operation for storing the weights W11, W12, W21 and W22 of the neural network described above by referring to FIG. 60 in the memory cells MC1 to MC4 will be described. The memory cells MC1 to MC4 may be at least portions of the memory cells included in the semiconductor device, and may be defined as weight cells storing the weights W11, W12, W21 and W22. In an example embodiment, the weights W11, W12, W21 and W22 may be matched with the memory cells MC1 to MC4 and may be stored in the memory cells MC1 to MC4 as illustrated in Table 1 below.

TABLE 1

| Memory Cell | Weight |
|---|---|
| MC1 | W11 |
| MC2 | W12 |
| MC3 | W21 |
| MC4 | W22 |

Referring to FIG. 61, a negative voltage, lower than the threshold voltage of the second transistor TR2, may be input to the first word line WL1, thus turning on the second transistor TR2 in each of the first memory cell MC1 and the second memory cell MC2. Since the negative voltage is input to the first word line WL1, the first transistor TR1 may be turned off in each of the first memory cell MC1 and the second memory cell MC2. Meanwhile, a ground voltage may be input to the second word line WL2, and both the first transistor TR1 and the second transistor TR2 may be turned off in each of the third memory cell MC3 and the fourth memory cell MC4.

The semiconductor device may determine voltages of each of the first bit line BL1 and the second bit line BL2 according to the third weight W11 and the second weight W12. For example, when the first weight W11 is “0,” the voltage of the first bit line BL1 may be set to the first power voltage VSS as described above with reference to FIG. 5A, and when the first weight W11 is “1,” the voltage of the first bit line BL1 may be set to the second power voltage VCC. When the voltage of the first bit line BL1 is set to the first power voltage VSS, the charges of the storage node of the first memory cell MC1 may be removed, so that data “0” is written, and when the voltage of the first bit line BL1 is set to the second power voltage VCC, the charges may be stored in the storage node of the first memory cell MC1, so that data “1” may be written.

Next, referring to FIG. 62, a negative voltage, lower than the threshold voltage of the second transistor TR2, may be input to the second word line WL2, thus turning on the second transistor TR2 in each of the third memory cell MC3 and the fourth memory cell MC4. Since the negative voltage is input to the second word line WL2, the first transistor TR1 may be turned off in each of the third memory cell MC3 and the fourth memory cell MC4. Meanwhile, the ground voltage may be input to the first word line WL1, and both the first transistor TR1 and the second transistor TR2 may be turned off in each of the first memory cell MC1 and the second memory cell MC2.

Voltages of the first bit line BL1 and the second bit line BL2 may be set to voltages corresponding to the third weight W21 and the fourth weight W22, respectively, and then, the negative voltage may be input to the second word line WL2, so that the third weight W21 may be written to the third memory cell MC3, and the fourth weight W22 may be written to the fourth memory cell MC4. As described with reference to FIGS. 61 and 62, the weights W11, W12, W21 and W22 may be stored in the memory cells MC1 to MC4.

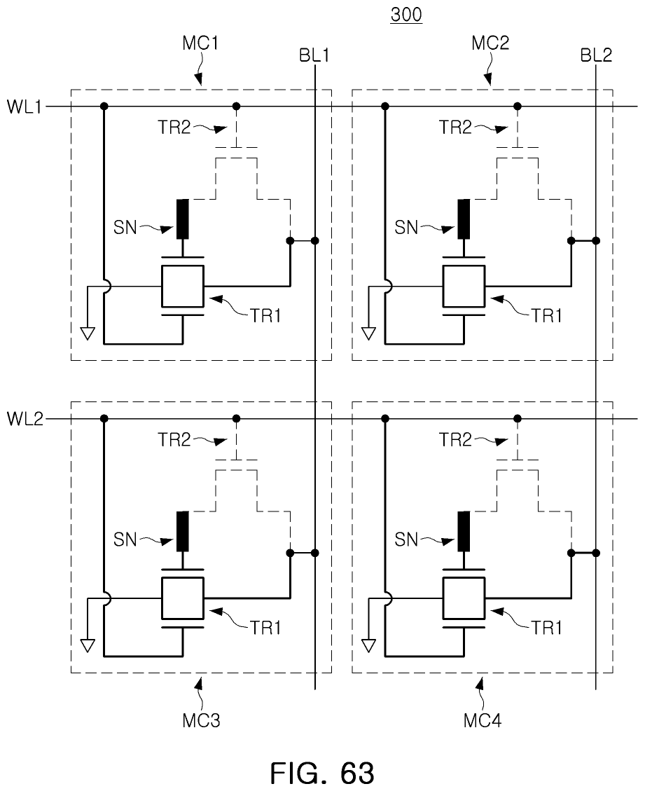

FIG. 63 may be a view illustrating an inference operation executed after storing the weights W11, W12, W21 and W22 in the memory cells MC1 to MC4. In the inference operation, the first transistor TR1 included in each of the memory cells MC1 to MC4 may be turned on and the second transistor TR2 may be turned off. However, in order to execute the operation described above with reference to mathematical expression 1, the first word line WL1 and the second word line WL2 may be selected and activated simultaneously.

Accordingly, the inference operation may be distinguished from a general read operation for reading stored data by activating only one select word line among the word lines WL1 and WL2. A semiconductor device may distinguish the read operation and the inference operation by defining the read operation and the inference operation as different modes. In the mode of executing the read operation, a row decoder in a peripheral circuit region may activate the select word lines one by one among the word lines WL1 and WL2, while in the mode of executing the inference operation, the row decoder may activate two or more select word lines among the word lines WL1 and WL2 simultaneously.

Referring to FIG. 63, the word lines WL1 and WL2 may be activated simultaneously, and the first transistor TR1 in each of the memory cells MC1 to MC4 may be turned on or off by the voltage input to the word lines WL1 and WL2. Meanwhile, while executing the inference operation, the second transistor TR2 in each of the memory cells MC1 to MC4 may be maintained in a turn-off state.

In an example embodiment illustrated in FIG. 63, it is assumed that each of the nodes N11 and N12 of the first layer L1 outputs data “1.” Accordingly, the first transistor TR1 in the memory cells MC1 to MC4 may be turned on by the voltages input to each of the word lines WL1 and WL2. Assuming that the first node N11 of the first layer L1 outputs data “1” and the second node N12 outputs data “0,” the first transistor TR1 of each of the first and second memory cells MC1 and MC2 connected to the first word line WL1 may be turned on, and the first transistor TR1 of each of the third and fourth memory cells MC3 and MC4 may be turned off.

The voltage of the first bit line BL1 may be determined by a current of the first memory cell MC1 and a current of the third memory cell MC3. A voltage corresponding to the output data of the first node N11 of the first layer L1 may be input to the first word line WL1, and a voltage corresponding to the output data of the second node N12 of the first layer L1 may be input to the second word line WL2. Meanwhile, the first weight W11 may be stored in the first memory cell MC1, and the third weight W21 may be stored in the third memory cell MC3, so that a voltage level of the first bit line BL1 may have a size corresponding to [N11*W11+N12*W21], which is an operation result input to the first node N21 of the second layer L2.

Meanwhile, the voltage of the second bit line BL2 may be determined by a current of the second memory cell MC2 and a current of the fourth memory cell MC4. The second weight W12 may be stored in the second memory cell MC2, and the fourth weight W22 may be stored in the fourth memory cell MC4, so that a voltage level of the second bit line BL2 may have a size corresponding to [N11*W12+N12*W22], which is an operation result input to the second node N22 of the second layer L2.

The first bit line BL1 may be connected to a first sense amplifier, and the second bit line BL2 may be connected to a second sense amplifier. Each of a voltage level input to the first sense amplifier and a voltage level input to the second sense amplifier may be determined according to the data output by each of the nodes N11 and N12 of the first layer L1, and the weights W11, W12, W21 and W22. The voltage level of the first bit line BL1 input to the first sense amplifier may correspond to the data input to the first node N21 of the second layer L2, and the voltage level of the second bit line BL2 input to the second sense amplifier may correspond to the data input to the second node N22 of the second layer L2.

For example, when the weights W11, W12, W21 and W22 are all data “0,” charges may not be stored in the storage nodes of each of the memory cells MC1 to MC4. Accordingly, regardless of the output data of the nodes N11 and N12 of the first layer L1 determining the voltages of the word lines WL1 and WL2, each of the voltages of the first bit line BL1 and the second bit line BL2 may have a level close to the reference level.

As another example, when each of the first weight W11 and the second weight W12 is data “1” and each of the third weight W21 and the fourth weight W22 is data “0,” the voltages of the bit lines BL1 and BL2 may vary depending on the voltages of the word lines WL1 and WL2. For example, when the output data of each of the nodes N11 and N12 of the first layer L1 is “1,” the voltages of the first bit line BL1 and the second bit line BL2 may have a first level higher than a reference level.

As another example, it is assumed that each of the first to third weights W11, W12 and W21 is data “1” and the fourth weight W22 is data “0”. In this case, when the output data of each of the nodes N11 and N12 of the first layer L1 is “1,” the voltage of the first bit line BL1 may have a second level higher than the first level, and the voltage of the second bit line BL2 may have the first level. In this manner, a Multiply and Accumulation (MAC) operation result obtained by multiplying and adding the output data of the nodes N11 and N12 of the first layer L1 by the weights W11, W12, W21 and W22 may be output through the bit lines BL1 and BL2.

As described above, the semiconductor device according to an example embodiment of the present disclosure may support a neural network-based inference operation based on the characteristic in which data stored in the storage node is not lost after the read operation. The inference operation may be implemented by simply activating two or more word lines simultaneously in the row decoder without changing the design of the peripheral circuit region, and the inference operation may be executed only with a memory device that may store and read data without a separate neural processor.

The present disclosure is not limited to the above-described embodiments and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

What is claimed is:

1. A semiconductor device, comprising:
a cell region in which a plurality of unit structures are arranged in a first direction, perpendicular to an upper surface of a substrate, and a second direction and a third direction, parallel to the upper surface of the substrate and intersecting each other; and
a peripheral circuit region including circuits configured for controlling the plurality of unit structures in the cell region,
wherein each of the plurality of unit structures includes:
a first gate electrode layer and a second gate electrode layer separated from each other in the first direction and extending in the second direction;
a first semiconductor layer and a second semiconductor layer separated from each other in the first direction and between the first gate electrode layer and the second gate electrode layer in the first direction, and extending in the third direction;
a plurality of insulating layers between the first gate electrode layer, the second gate electrode layer, the first semiconductor layer and the second semiconductor layer in the first direction; and
a bit line electrode layer extending in the first direction and electrically connected to the first semiconductor layer and the second semiconductor layer in the third direction.

2. The semiconductor device of claim 1, wherein the peripheral circuit region includes:
a row decoder electrically connected to the first gate electrode layer and the second gate electrode layer of each of the plurality of unit structures through a plurality of word lines; and
a sense amplifier circuit electrically connected to the bit line electrode layer of each of the plurality of unit structures through a plurality of bit lines, and
wherein the first gate electrode layer and the second gate electrode layer included in one of the plurality of unit structures are commonly connected to one of the plurality of word lines.

3. The semiconductor device of claim 1, wherein the first gate electrode layer and the second gate electrode layer are offset from one another in the third direction.

4. The semiconductor device of claim 3, wherein in the first direction, the first gate electrode layer and the second gate electrode layer are non-overlapping with respect to each other.

5. The semiconductor device of claim 1, wherein the plurality of insulating layers include:
a first insulating layer between the first semiconductor layer and the first gate electrode layer in the first direction;
a second insulating layer between the second semiconductor layer and the second gate electrode layer in the first direction; and
a third insulating layer between the first semiconductor layer and the second semiconductor layer in the first direction.

6. The semiconductor device of claim 5, wherein the third insulating layer includes a different material from the first insulating layer and the second insulating layer.

7. The semiconductor device of claim 5, wherein in the third direction, a length of the third insulating layer is greater than a length of the second semiconductor layer.

8. The semiconductor device of claim 1, wherein the plurality of unit structures include a first unit structure and a second unit structure aligned with one another in the first direction and the third direction and arranged in the second direction, and
the first unit structure and the second unit structure share the first gate electrode layer and the second gate electrode layer.

9. The semiconductor device of claim 8, wherein a first portion of the first semiconductor layer included in the first unit structure is separated from a second portion of the first semiconductor layer included in the second unit structure, and a first portion of the second semiconductor layer included in the first unit structure is separated from a second portion of the second semiconductor layer included in the second unit structure.

10. The semiconductor device of claim 1, wherein, in the second direction, a maximum width of the first semiconductor layer is less than a maximum width of the second semiconductor layer.

11. The semiconductor device of claim 1, further comprising:
a first transistor comprising at least a portion of the first gate electrode layer and the first semiconductor layer; and
a second transistor comprising at least a portion of the second gate electrode layer and the second semiconductor layer.

12. The semiconductor device of claim 11, wherein a first threshold voltage of the first transistor is different from a second threshold voltage of the second transistor.

13. The semiconductor device of claim 12, wherein the first threshold voltage is a positive voltage and the second threshold voltage is a negative voltage.

14. The semiconductor device of claim 1, wherein a thickness of the first semiconductor layer in the first direction is less than a width of the first semiconductor layer in the second direction, and
a thickness of the second semiconductor layer in the first direction is less than a width of the second semiconductor layer in the second direction.

15. A semiconductor device, comprising:
a cell region including a plurality of memory cells electrically connected to a plurality of word lines and a plurality of bit lines; and
a peripheral circuit region including circuits configured for controlling the plurality of memory cells through the plurality of word lines and the plurality of bit lines,
wherein each of the plurality of memory cells includes a first transistor and a second transistor, and the first transistor includes a first gate and first active regions, and the second transistor includes a second gate and second active regions, and
in each of the plurality of memory cells, the first gate and the second gate are commonly connected to one of the plurality of word lines, a first one of the first active regions and a first one of the second active regions are commonly connected to one of the plurality of bit lines, a second one of the first active regions is connected to a ground node supplying a ground voltage, and a second one of the second active regions is configured as a storage node in which a charge representing a logic state of the memory cell is stored.

16. The semiconductor device of claim 15, wherein the peripheral circuit region includes:
a row decoder electrically connected to the plurality of memory cells through the plurality of word lines; and
a sense amplifier circuit electrically connected to the plurality of memory cells through the plurality of bit lines.

17. The semiconductor device of claim 16, wherein during a read operation for a selected memory cell among the plurality of memory cells, the row decoder is configured to provide a first turn-on voltage to a select word line connected to the selected memory cell to turn on the first transistor.

18. The semiconductor device of claim 16, wherein during a write operation for a selected memory cell among the plurality of memory cells, the row decoder is configured to provide a predetermined write bias voltage to a select bit line connected to the select memory cell, and inputs a second turn-on voltage to a select word line connected to the selected memory cell to turn on the second transistor.

19. The semiconductor device of claim 15, wherein weights of a trained neural network are stored in at least a subset of the plurality of memory cells, and
the peripheral circuit region is configured to simultaneously provide voltages corresponding to output data of nodes included in a first layer of the neural network to a portion of the plurality of word lines connected to the at least a subset of the plurality of memory cells, and to read voltages corresponding to data input to nodes of a second layer connected to the first layer in the neural network from a portion of the plurality of bit lines connected to the at least a subset of the plurality of memory cells.

20. A semiconductor device, comprising:
a plurality of memory cells connected to a plurality of word lines and a plurality of bit lines;
a row decoder configured to control voltages on each of the plurality of word lines; and
a sense amplifier circuit configured to control voltages on each of the plurality of bit lines,
wherein each of the plurality of memory cells includes a pair of transistors,
the row decoder is configured to provide a common control voltage to the pair of transistors included in a selected memory cell among the plurality of memory cells, through one select word line of the plurality of word lines, and
a first transistor of the pair of transistors is turned on and a second transistor of the pair of transistors is turned off by the common control voltage.
